(19) United States
(12) Patent Application Publication
(10) Pub. No.: US 2026/0065950 A1
(43) Pub. Date: Mar. 5, 2026

(54) SEMICONDUCTOR MEMORY DEVICE

(71) Applicant: Kioxia Corporation, Tokyo (JP)

(72) Inventor: Hideto TAKEKIDA, Yokohama Kanagawa (JP)

(73) Assignee: Kioxia Corporation, Tokyo (JP)

(21) Appl. No.: 19/061,601

(22) Filed: Feb. 24, 2025

(30) Foreign Application Priority Data
Sep. 4, 2024 (JP) 2024-152323

(51) Int. Cl. G11C 5/06; G11C 16/04; H10B 41/10; H10B 41/27; H10B 41/35; H10D 64/66

(52) U.S. Cl. CPC G11C 5/063; G11C 16/0483; H10B 41/10; H10B 41/27; H10B 41/35; H10D 64/666; H10D 64/667

(57) ABSTRACT

According to one embodiment, a semiconductor memory device includes: a substrate; a layer stack disposed above the substrate in a first direction; a first conductive layer disposed between the substrate and the layer stack; a memory pillar including a semiconductor film, extending in the first direction, and penetrating the first conductive layer; and a first member disposed apart from the memory pillar in a second direction intersecting the first direction, extending in the first direction, and penetrating the first conductive layer. The layer stack has a structure in which a first semiconductor layer, a second semiconductor layer, a second conductive layer, and a third conductive layer are stacked in order from a side of the substrate. The first semiconductor layer covers an end portion of the semiconductor film in the first direction and an end portion of the first member in the first direction.

### CROSS-REFERENCE TO RELATED APPLICATIONS

This application is based upon and claims the benefit of priority from Japanese Patent Application No. 2024-152323, filed Sep. 4, 2024, the entire contents of which are incorporated herein by reference.

### FIELD

Embodiments described herein relate generally to a semiconductor memory device.

### BACKGROUND

A NAND flash memory is known as a semiconductor memory device capable of storing data in a nonvolatile manner.

### BRIEF DESCRIPTION OF DRAWINGS

FIG. 1 is a block diagram illustrating an example of a configuration of a memory system including a semiconductor memory device according to a first embodiment.

FIG. 2 is a circuit diagram illustrating an example of a circuit configuration of a memory cell array included in the semiconductor memory device according to the first embodiment.

FIG. 3 is a perspective view illustrating an outline of a bonding structure of the semiconductor memory device according to the first embodiment.

FIG. 4 is a plan view illustrating an example of a planar layout of the memory cell array included in the semiconductor memory device according to the first embodiment.

FIG. 5 is a plan view illustrating an example of a planar layout of the memory cell array in a memory region of the semiconductor memory device according to the first embodiment.

FIG. 6 is a cross-sectional view taken along line VI-VI of FIG. 5, illustrating an example of a cross-sectional structure of the memory cell array in the memory region of the semiconductor memory device according to the first embodiment.

FIG. 7 is a cross-sectional view taken along line VII-VII of FIG. 6, illustrating an example of a cross-sectional structure of a memory pillar included in the semiconductor memory device according to the first embodiment.

FIG. 8 is a cross-sectional view illustrating an example of a cross-sectional structure of the semiconductor memory device according to the first embodiment.

FIG. 9 is an enlarged cross-sectional view of a partial region including a layer stack of FIG. 8.

FIG. 10 is a cross-sectional view for describing an example of a method of manufacturing the semiconductor memory device according to the first embodiment.

FIG. 11 is a cross-sectional view for describing an example of the method of manufacturing the semiconductor memory device according to the first embodiment.

FIG. 12 is a cross-sectional view for describing an example of the method of manufacturing the semiconductor memory device according to the first embodiment.

FIG. 13 is a cross-sectional view for describing an example of the method of manufacturing the semiconductor memory device according to the first embodiment.

FIG. 14 is a cross-sectional view for describing an example of the method of manufacturing the semiconductor memory device according to the first embodiment.

FIG. 15 is a cross-sectional view for describing an example of the method of manufacturing the semiconductor memory device according to the first embodiment.

FIG. 16 is a cross-sectional view for describing an example of the method of manufacturing the semiconductor memory device according to the first embodiment.

FIG. 17 is a cross-sectional view for describing an example of the method of manufacturing the semiconductor memory device according to the first embodiment.

FIG. 18 is a cross-sectional view illustrating an example of a cross-sectional structure of a semiconductor memory device according to a second embodiment.

FIG. 19 is an enlarged cross-sectional view of a partial region including a layer stack of FIG. 18.

FIG. 20 is a cross-sectional view for describing an example of a method of manufacturing the semiconductor memory device according to the second embodiment.

FIG. 21 is a cross-sectional view for describing an example of the method of manufacturing the semiconductor memory device according to the second embodiment.

FIG. 22 is a cross-sectional view illustrating an example of a cross-sectional structure of a semiconductor memory device according to a third embodiment.

FIG. 23 is an enlarged cross-sectional view of a partial region including a layer stack of FIG. 22.

FIG. 24 is a cross-sectional view for describing an example of a method of manufacturing the semiconductor memory device according to the third embodiment.

FIG. 25 is a cross-sectional view for describing an example of the method of manufacturing the semiconductor memory device according to the third embodiment.

FIG. 26 is a cross-sectional view for describing an example of the method of manufacturing the semiconductor memory device according to the third embodiment.

FIG. 27 is a cross-sectional view illustrating an example of a cross-sectional structure of a semiconductor memory device according to a first modification of the third embodiment.

FIG. 28 is an enlarged cross-sectional view of a partial region including a layer stack of FIG. 27.

FIG. 29 is a cross-sectional view illustrating an example of a cross-sectional structure of a semiconductor memory device according to a second modification of the third embodiment.

FIG. 30 is an enlarged cross-sectional view of a partial region including a layer stack of FIG. 29.

FIG. 31 is a cross-sectional view illustrating an example of a cross-sectional structure of a semiconductor memory device according to a fourth embodiment.

FIG. 32 is an enlarged cross-sectional view of a partial region including a layer stack of FIG. 31.

FIG. 33 is a cross-sectional view for describing an example of a method of manufacturing the semiconductor memory device according to the fourth embodiment.

FIG. 34 is a cross-sectional view illustrating an example of a cross-sectional structure of a semiconductor memory device according to a fifth embodiment.

FIG. 35 is an enlarged cross-sectional view of a partial region including a layer stack of FIG. 34.

FIG. 36 is a cross-sectional view for describing an example of a method of manufacturing the semiconductor memory device according to the fifth embodiment.

FIG. 37 is a cross-sectional view illustrating an example of a cross-sectional structure of a semiconductor memory device according to a sixth embodiment.

FIG. 38 is an enlarged cross-sectional view of a partial region including a layer stack of FIG. 37.

FIG. 39 is a cross-sectional view illustrating an example of a cross-sectional structure of a semiconductor memory device according to a seventh embodiment.

FIG. 40 is an enlarged cross-sectional view of a partial region including a layer stack of FIG. 39.

FIG. 41 is a cross-sectional view illustrating an example of a cross-sectional structure of a semiconductor memory device according to a first modification of the seventh embodiment.

FIG. 42 is an enlarged cross-sectional view of a partial region including a layer stack of FIG. 41.

FIG. 43 is a cross-sectional view illustrating an example of a cross-sectional structure of a semiconductor memory device according to a second modification of the seventh embodiment.

FIG. 44 is an enlarged cross-sectional view of a partial region including a layer stack of FIG. 43.

FIG. 45 is a cross-sectional view illustrating an example of a cross-sectional structure of a semiconductor memory device according to an eighth embodiment.

FIG. 46 is an enlarged cross-sectional view of a partial region including a layer stack of FIG. 45.

### DETAILED DESCRIPTION

In general, according to one embodiment, a semiconductor memory device includes: a substrate; a layer stack disposed above the substrate in a first direction; a first conductive layer disposed between the substrate and the layer stack; a memory pillar including a semiconductor film, extending in the first direction, and penetrating the first conductive layer; and a first member disposed apart from the memory pillar in a second direction intersecting the first direction, extending in the first direction, and penetrating the first conductive layer. The layer stack has a structure in which a first semiconductor layer, a second semiconductor layer, a second conductive layer, and a third conductive layer are stacked in order from a side of the substrate. The first semiconductor layer covers an end portion of the semiconductor film in the first direction and an end portion of the first member in the first direction. Hereinafter, embodiments will be described with reference to the drawings. Dimensions and ratios of the drawings are not necessarily the same as actual ones. Note that, in the following description, elements having substantially the same function and configuration are denoted by the same reference numerals. In a case where elements having similar configurations are particularly distinguished from each other, different letters or numbers may be added to the end of the same reference numeral.

### 1. First Embodiment

### 1.1 Configuration

### 1.1.1 Configuration of Memory System

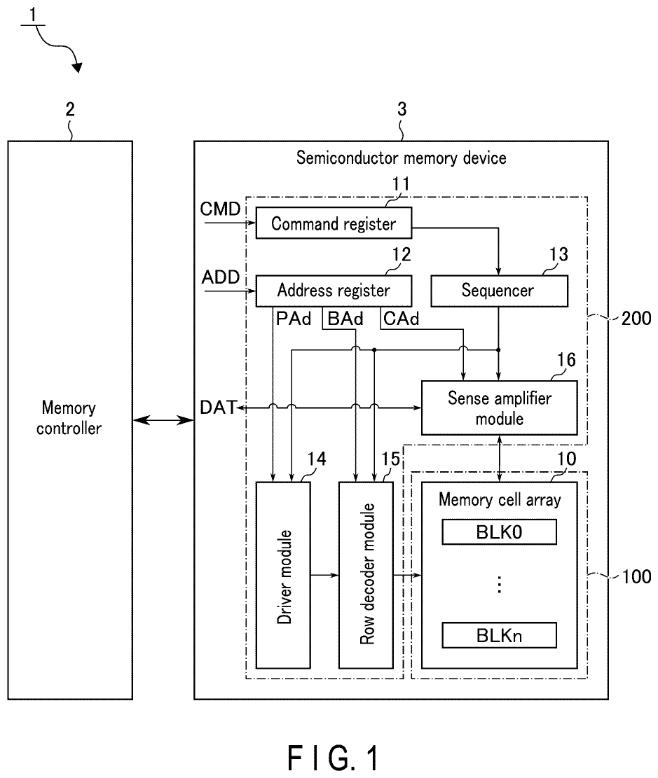

A configuration of a memory system including a semiconductor memory device according to a first embodiment will be described with reference to FIG. 1. FIG. 1 is a block diagram illustrating an example of a configuration of a memory system. A memory system 1 is a memory device configured to be connected to an external host device (not illustrated). The memory system 1 is, for example, a memory card such as an SD™ card, a universal flash storage (UFS), or a solid state drive (SSD). As illustrated in FIG. 1, the memory system 1 includes a memory controller 2 and a semiconductor memory device 3.

The memory controller 2 is, for example, an integrated circuit such as a system-on-a-chip (SoC). The memory controller 2 controls the semiconductor memory device 3 based on a request from the host device. For example, the memory controller 2 writes data requested to be written from the host device to the semiconductor memory device 3. Further, the memory controller 2 reads data requested to be read from the host device from the semiconductor memory device 3 and transmits the data to the host device.

The semiconductor memory device 3 is a memory that stores data in a nonvolatile manner. The semiconductor memory device 3 is, for example, a NAND flash memory. Hereinafter, a NAND flash memory will be described as an example of the semiconductor memory device 3.

### 1.1.2 Configuration of Semiconductor Memory Device

Subsequently, the configuration of the semiconductor memory device 3 will be described with reference to FIG. 1. As illustrated in FIG. 1, the semiconductor memory device 3 includes an array chip 100 and a circuit chip 200.

The array chip 100 includes, for example, a memory cell array 10.

The memory cell array 10 includes a plurality of blocks BLK0 to BLKn (n is an integer of 1 or more). The block BLK is a set of a plurality of memory cell transistors capable of storing data in a nonvolatile manner. The block BLK is used as, for example, a data erasing unit. Further, a plurality of bit lines and a plurality of word lines are provided in the memory cell array 10. Each memory cell transistor is associated with, for example, one bit line and one word line. A detailed configuration of the memory cell array 10 will be described later.

The circuit chip 200 includes, for example, a command register 11, an address register 12, a sequencer 13, a driver module 14, a row decoder module 15, and a sense amplifier module 16. Hereinafter, the command register 11, the address register 12, the sequencer 13, the driver module 14, the row decoder module 15, and the sense amplifier module 16 are collectively referred to as “peripheral circuits”.

The command register 11 is a circuit that stores a command CMD received by the semiconductor memory device 3 from the memory controller 2. The command CMD includes, for example, a command for causing the sequencer 13 to execute a read operation, a write operation, an erase operation, and the like.

The address register 12 is a circuit that stores an address ADD received by the semiconductor memory device 3 from the memory controller 2. The address ADD includes, for example, a block address BAd, a page address PAd, and a column address CAd. For example, the block address BAd, the page address PAd, and the column address CAd are used to select the block BLK, the word line, and the bit line, respectively.

The sequencer 13 is a circuit that controls operations of other circuits according to a predetermined program. The sequencer 13 controls the entire operation of the semiconductor memory device 3. For example, the sequencer 13 controls the driver module 14, the row decoder module 15, the sense amplifier module 16, and the like based on the command CMD stored in the command register 11. For example, the sequencer 13 executes the read operation, the write operation, the erase operation, and the like.

The driver module 14 is a circuit that generates a voltage used in the read operation, the write operation, the erase operation, and the like. The driver module 14 applies the generated voltage to a signal line corresponding to the selected word line based on, for example, the page address PAd stored in the address register 12.

The row decoder module 15 is a circuit that selects one corresponding block BLK in the memory cell array 10 based on the block address BAd stored in the address register 12. The row decoder module 15 transfers, for example, the voltage applied to the signal line corresponding to the selected word line to the selected word line in the selected block BLK.

The sense amplifier module 16 is a circuit that selects a bit line based on the column address CAd stored in the address register 12. For example, in the write operation, the sense amplifier module 16 applies a voltage based on write data DAT received from the memory controller 2 to the selected bit line. Further, in the read operation, the sense amplifier module 16 determines data stored in the memory cell transistor based on the voltage of the selected bit line. The sense amplifier module 16 transfers a determination result to the memory controller 2 as read data DAT.

### 1.1.3 Circuit Configuration of Memory Cell Array

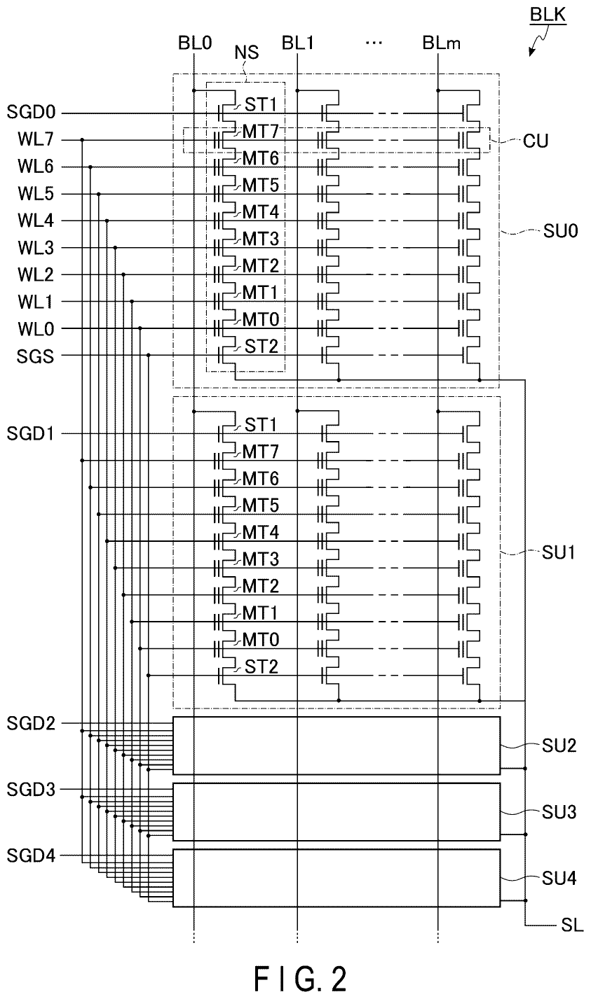

A circuit configuration of the memory cell array 10 will be described with reference to FIG. 2. FIG. 2 is a circuit diagram illustrating an example of a circuit configuration of the memory cell array 10. FIG. 2 illustrates one block BLK of the plurality of blocks BLK included in the memory cell array 10. As illustrated in FIG. 2, the block BLK includes, for example, five string units SU0 to SU4. The string unit SU is a set of NAND strings NS to be described later. For example, in the write operation or the read operation, the NAND strings NS in the string unit SU are collectively selected.

Each string unit SU includes a plurality of NAND strings NS respectively associated with bit lines BL0 to BLm (m is an integer of 1 or more). Each NAND string NS includes, for example, memory cell transistors MT0 to MT7 and select transistors ST1 and ST2. Each memory cell transistor MT includes a control gate and a charge storage layer, and stores data in a nonvolatile manner. Each of the select transistors ST1 and ST2 is used to select the string unit SU during various operations.

In each NAND string NS, the memory cell transistors MT0 to MT7 are connected in series. A drain of the select transistor ST1 is connected to the associated bit line BL. A source of the select transistor ST1 is connected to one end of the memory cell transistors MT0 to MT7 connected in series. The drain of the select transistor ST2 is connected to the other end of the memory cell transistors MT0 to MT7 connected in series. The source of the select transistor ST2 is connected to a source line SL.

In the same block BLK, the control gates of the memory cell transistors MT0 to MT7 are connected to word lines WL0 to WL7, respectively. Gates of the select transistors ST1 in the string units SU0 to SU4 are connected to select gate lines SGDO to SGD4, respectively. Gates of the select transistors ST2 in the string units SU0 to SU4 are connected to a select gate line SGS.

Different column addresses CAd are allocated to the bit lines BL0 to BLm, respectively. Each bit line BL is shared by the NAND strings NS to which the same column address CAd is allocated among the plurality of blocks BLK. The word lines WL0 to WL7 are provided for each block BLK. The source line SL is shared among the plurality of blocks BLK, for example.

A set of the plurality of the memory cell transistors MT connected to the common word line WL in one string unit SU is referred to as, for example, a cell unit CU. For example, a memory capacity of the cell unit CU including the memory cell transistors MT each storing 1-bit data is defined as “1-page data”. The cell unit CU can have the memory capacity of two page data or more based on the number of bits of data stored in the memory cell transistor MT.

Note that the circuit configuration of the memory cell array 10 is not limited to the configuration described above. For example, the number of string units SU included in each block BLK can be designed to arbitrary number. The numbers of the memory cell transistors MT and the select transistors ST1 and ST2 included in each NAND string NS can be designed to arbitrary numbers.

### 1.1.4 Bonding Structure of Semiconductor Memory Device

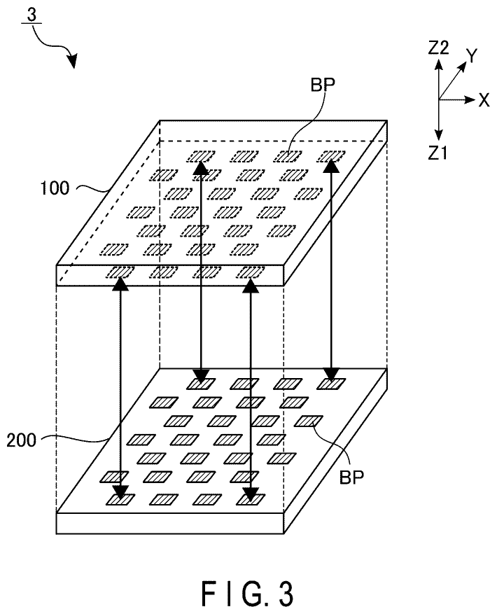

An outline of a bonding structure of the semiconductor memory device 3 will be described with reference to FIG. 3. FIG. 3 is a perspective view illustrating the outline of the bonding structure of the semiconductor memory device 3.

As illustrated in FIG. 3, the semiconductor memory device 3 has a structure in which the array chip 100 is bonded to the circuit chip 200. Each of the array chip 100 and the circuit chip 200 includes a plurality of bonding pads BP provided on surfaces facing each other. In the bonding structure, the bonding pad BP of the array chip 100 and the bonding pad BP of the circuit chip 200 are bonded to form one bonding pad BP. In other words, an electrode (conductor) constituting the bonding pad BP provided on the array chip 100 and an electrode (conductor) constituting the bonding pad BP provided on the circuit chip 200 are bonded to each other to form the bonding pad BP.

Hereinafter, a surface (hereinafter referred to as “bonding surface”) on which the array chip 100 and the circuit chip 200 are bonded is referred to as an XY surface. Directions orthogonal to each other in the XY surface are defined as an X direction and a Y direction. Further, a direction substantially perpendicular to the XY plane and from the array chip 100 toward the circuit chip 200 is defined as a Z1 direction. A direction substantially perpendicular to the XY plane and from the circuit chip 200 toward the array chip 100 is defined as a Z2 direction. In a case where one of the Z1 direction and the Z2 direction is not limited, it is referred to as a Z direction. Further, in the array chip 100, a surface on a bonding surface side of a certain component is referred to as a “first surface”, and a surface on a side opposite to the bonding surface of the certain component is referred to as a “second surface”. In the circuit chip 200, a surface on a bonding surface side of a certain component is referred to as a “first surface”, and a surface on a side opposite to the bonding surface of the certain component is referred to as a “second surface”.

### 1.1.5 Planar Structure of Memory Cell Array

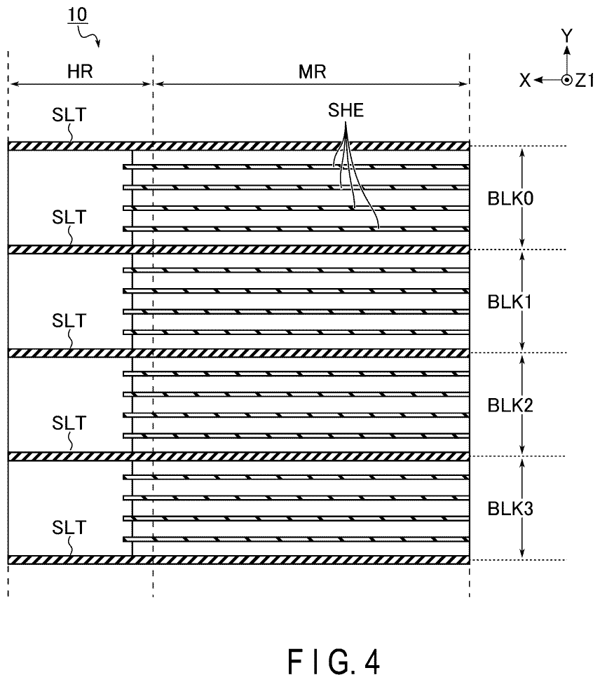

A planar structure of the memory cell array 10 will be described with reference to FIG. 4. FIG. 4 is a plan view illustrating an example of a planar layout of the memory cell array 10. FIG. 4 illustrates regions corresponding to the four blocks BLK0 to BLK3.

The memory cell array 10 includes a stacked wiring structure and a plurality of members SLT and SHE. The stacked wiring structure includes select gate lines SGD and SGS and the plurality of word lines WL. The stacked wiring structure is a structure stacked along the Z direction according to the number of stacked select gate lines SGD and SGS and the plurality of word lines WL. Note that, in the following description, the select gate lines SGD and SGS and the plurality of word lines WL are also collectively referred to as “stacked wirings”. Further, the memory cell array 10 includes, for example, a memory region MR and a hookup region HR arranged in the X direction. The memory region MR is a region in which data is substantially stored. Further, the memory region MR is a region used for connecting the bit line BL and the peripheral circuits. The hookup region HR is a region used for connecting the stacked wirings and the peripheral circuits.

The stacked wiring structure is provided over the memory region MR and the hookup region HR in the X direction, for example.

Each member SLT extends in the X direction. Each member SLT traverses the stacked wiring structure in the X direction across the memory region MR and the hookup region HR. Each member SLT has, for example, a structure in which an insulator and a plate-like conductor are embedded. Each member SLT divides the stacked wirings adjacent to each other via the member SLT. A region divided by the plurality of members SLT corresponds to one block BLK.

Each member SHE extends in the X direction. In the present embodiment, a case where four members SHE are provided between the adjacent members SLT will be described. Each member SHE traverses the stacked wiring structure in the X direction across the memory region MR. Each member SHE has, for example, a structure in which an insulator is embedded. Each member SHE divides the select gate lines SGD adjacent to each other via the member SHE, for example. Each of the regions divided by the plurality of members SLT and SHE corresponds to one string unit SU.

In the memory cell array 10, for example, the planar layout illustrated in FIG. 4 is repeatedly arranged in a Y direction.

Note that the planar layout of the memory cell array 10 is not limited to the above-described layout. For example, the number of members SHE arranged between the adjacent members SLT can be designed to be an arbitrary number according to the number of string units SU.

### 1.1.6 Structure of Memory Cell Array in Memory Region

The structure of the memory cell array 10 in the memory region MR will be described.

### 1.1.6.1 Planar Structure of Memory Cell Array in Memory Region

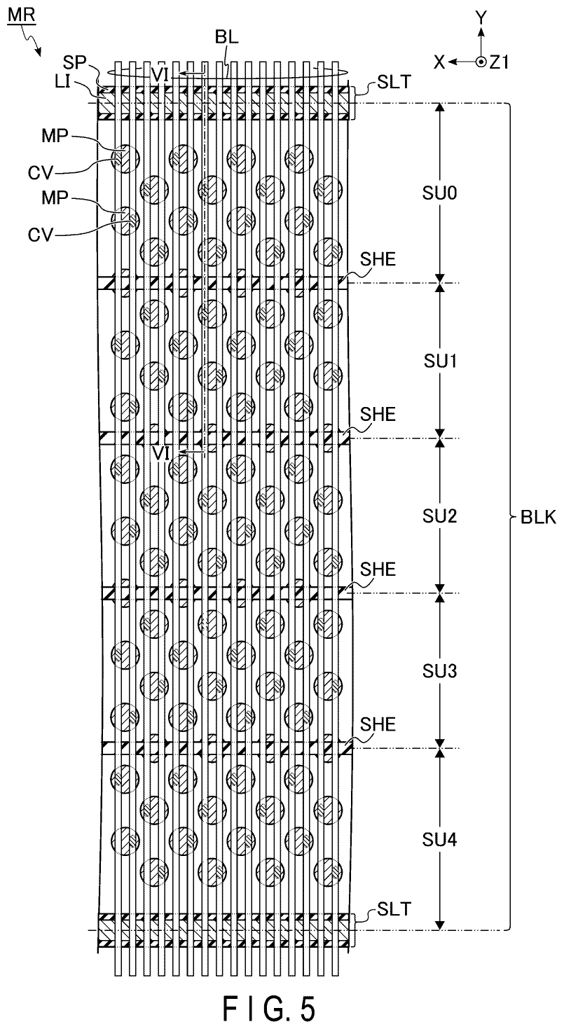

First, the planar structure of the memory cell array 10 in a memory region MR will be described with reference to FIG. 5. FIG. 5 is a plan view illustrating an example of the planar layout of the memory cell array 10 in the memory region MR.

As illustrated in FIG. 5, in the memory region MR, the memory cell array 10 includes a plurality of memory pillars MP, a plurality of contacts CV, and a plurality of the bit lines BL. Further, each member SLT includes a conductor LI and a spacer SP.

Each memory pillar MP functions as, for example, one NAND string NS. The plurality of memory pillars MP is arranged in twenty-four rows in a staggered manner, for example, in a region between the two adjacent members SLT. For example, one member SHE is arranged to overlap the memory pillars MP of the fifth row, the memory pillars MP of the tenth row, the memory pillars MP of the fifteenth row, and the memory pillar MP of the twentieth row when counted from an upper side of the drawing.

Each of the plurality of bit lines BL extends in the Y direction. Further, the plurality of bit lines BL is arranged in the X direction. Each bit line BL is arranged so as to overlap at least one memory pillar MP for each string unit SU. In the example of FIG. 5, each bit line BL is arranged so as to overlap two memory pillars MP for each string unit SU. One bit line BL of the plurality of bit lines BL overlapping the memory pillar MP is electrically connected to the memory pillar MP via the contact CV. For example, no contact is provided between the memory pillar MP overlapping the member SHE and the bit line BL. That is, the memory pillar MP overlapping the member SHE and the bit line BL are not electrically connected.

The conductor LI is a conductor provided extending in the X direction. The spacer SP is an insulator provided on a side surface of the conductor LI. The conductor LI is sandwiched between the spacers SP. The conductor LI and the stacked wirings adjacent to the conductor LI in the Y direction are electrically separated by the spacer SP. As a result, the conductor LI and the stacked wirings adjacent to the conductor LI in the Y direction are electrically insulated from each other.

### 1.1.6.2 Cross-Sectional Structure of Memory Cell Array in Memory Region

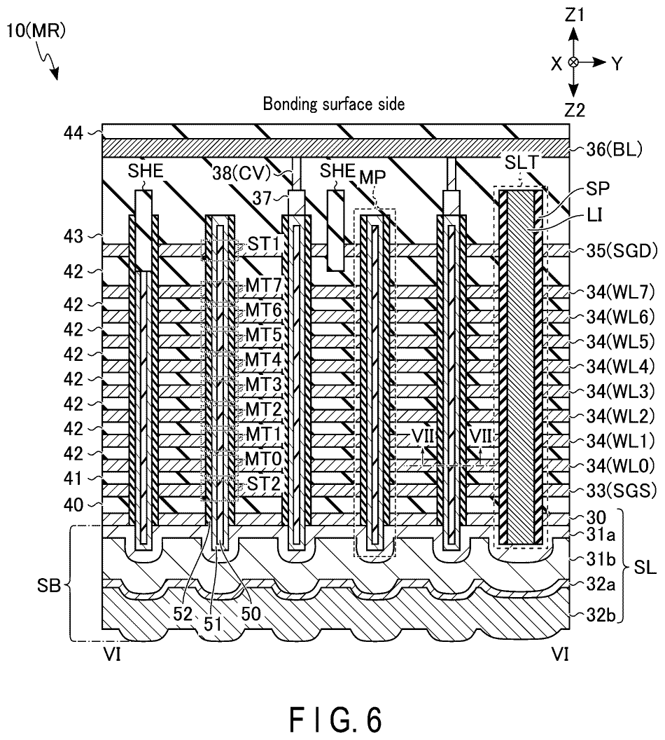

Next, a cross-sectional structure of the memory cell array 10 in the memory region MR will be described with reference to FIG. 6. FIG. 6 is a cross-sectional view taken along line VI-VI of FIG. 5, illustrating an example of a cross-sectional structure of the memory cell array 10 in the memory region MR. In FIG. 6, the upper side of the drawing corresponds to a bonding surface side.

As illustrated in FIG. 6, the memory cell array 10 further includes a conductive layer 30, semiconductor layers 31a and 31b, conductive layers 32a, 32b, 33, and 35, a plurality of conductive layers 34, 36, 37, and 38, insulating layers 40, 41, 43, and 44, and a plurality of insulating layers 42. FIG. 6 illustrates five memory pillars MP among the plurality of memory pillars MP. Further, FIG. 6 illustrates a case where eight conductive layers 34 and eight insulating layers 42 are included as the plurality of conductive layers 34 and the plurality of insulating layers 42.

The conductive layer 30 is provided in, for example, a plate shape extending along the XY plane. The conductive layer 30 is formed of a conductive material. The conductive material includes, for example, an N-type semiconductor doped with impurities.

The semiconductor layer 31a is provided on the second surface of the conductive layer 30. The semiconductor layer 31a includes, for example, doped polysilicon doped with an N-type impurity. As will be described later, the semiconductor layer 31a is formed on the second surface of each of the conductive layer 30, the plurality of memory pillars MP, and the plurality of members SLT. As a result, the second surface of the semiconductor layer 31a has irregularities corresponding to the plurality of memory pillars MP, for example. That is, the second surface of the semiconductor layer 31a may not be flat.

The semiconductor layer 31b is provided on the second surface of the semiconductor layer 31a. The semiconductor layer 31b includes, for example, doped polysilicon doped with an N-type impurity. As will be described later, the semiconductor layer 31b is formed on the second surface of the semiconductor layer 31a. As a result, the second surface of the semiconductor layer 31b has irregularities, similarly to the second surface of the semiconductor layer 31a, for example. That is, the second surface of the semiconductor layer 31b may not be flat, similarly to the second surface of the semiconductor layer 31a.

The conductive layer 32a is provided on the second surface of the semiconductor layer 31b. The conductive layer 32a includes, for example, titanium or titanium nitride. The conductive layer 32a functions as a barrier metal of the conductive layer 32b. As will be described later, the conductive layer 32a is formed on the second surface of the semiconductor layer 31b. As a result, the second surface of the conductive layer 32a has irregularities, similarly to the second surface of the semiconductor layer 31b, for example. That is, the second surface of the conductive layer 32a may not be flat, similarly to the second surface of the semiconductor layer 31b.

The conductive layer 32b is provided on the second surface of the conductive layer 32a. The conductive layer 32b includes, for example, tungsten. As will be described later, the conductive layer 32b is formed on the second surface of the conductive layer 32a. As a result, the second surface of the conductive layer 32b has irregularities, similarly to the second surface of the conductive layer 32a, for example. That is, the second surface of the conductive layer 32b may not be flat, similarly to the second surface of the conductive layer 32a.

The conductive layer 30, the semiconductor layers 31a and 31b, and the conductive layers 32a and 32b provided as described above function as the source lines SL. By stacking polysilicon (the conductive layer 30 and the semiconductor layers 31a and 31b) and metal (the conductive layers 32a and 32b), a resistance of source line SL can be reduced. Hereinafter, the stacked structure provided on the second surface of the conductive layer 30 is referred to as a “layer stack SB”. In the present embodiment, the layer stack SB has a structure in which the semiconductor layer 31a, the semiconductor layer 31b, the conductive layer 32a, and the conductive layer 32b are stacked in this order from the conductive layer 30 side.

The insulating layer 40 is provided on the first surface of the conductive layer 30. The insulating layer 40 includes, for example, silicon oxide. The conductive layer 33 is provided on the first surface of the insulating layer 40. The conductive layer 33 is provided in a plate shape extending along the XY plane, for example. The conductive layer 33 functions as the select gate line SGS. The conductive layer 33 includes, for example, tungsten.

The insulating layer 41 is provided on the first surface of the conductive layer 33. The insulating layer 41 includes, for example, silicon oxide. On the first surface of the insulating layer 41, eight conductive layers 34 and eight insulating layers 42 are stacked in the order of the conductive layer 34, the insulating layers 42, . . . , the conductive layer 34, and the insulating layer 42 in the Z1 direction. The conductive layer 34 is provided in a plate shape extending along the XY plane, for example. The eight conductive layers 34 respectively function as the word lines WL0 to WL7 in order along the Z1 direction. The conductive layer 34 includes, for example, tungsten. The insulating layer 42 includes, for example, silicon oxide.

The conductive layer 35 is provided on the first surface of the uppermost insulating layer 42 in the Z1 direction among the eight insulating layers 42. The conductive layer 35 is provided in a plate shape extending along the XY plane, for example. The conductive layer 35 functions as the select gate line SGD. The conductive layer 35 is electrically insulated for each string unit SU by, for example, the plurality of members SHE. The conductive layer 35 includes, for example, tungsten.

The insulating layer 43 is provided on the first surface of the conductive layer 35. The insulating layer 43 includes, for example, silicon oxide. The plurality of conductive layers 36 is provided on the first surface of the insulating layer 43. Each conductive layer 36 is provided extending along the Y direction. FIG. 6 illustrates one conductive layer 36 of the plurality of conductive layers 36. Each conductive layer 36 functions as the bit line BL. The plurality of conductive layers 36 is electrically connected to the plurality of memory pillars MP via the plurality of conductive layers 37 and 38. The conductive layer 36 includes, for example, copper.

The insulating layer 44 is provided on the first surface of the conductive layer 36. The insulating layer 44 includes, for example, silicon oxide.

In the Z1 direction, the plurality of memory pillars MP is provided extending along the Z direction below the plurality of conductive layers 36. The first surface of each of the plurality of memory pillars MP is located between the conductive layer 35 and the conductive layer 36, for example. The plurality of memory pillars MP penetrates the conductive layers 30, 33, and 35 and the plurality of conductive layers 34.

Each of the plurality of memory pillars MP includes, for example, a core member 50, a semiconductor film 51, and a stacked film 52. The core member 50 is provided extending along the Z direction. The semiconductor film 51 covers a periphery of the core member 50. An end portion of the semiconductor film 51 in the Z2 direction is in contact with the semiconductor layer 31a. The stacked film 52 covers a side surface of the semiconductor film 51 except for the portion where the semiconductor film 51 and the semiconductor layer 31a are in contact with each other. The core member 50 includes an insulator such as silicon oxide. The semiconductor film 51 includes, for example, silicon. The configuration of the stacked film 52 will be described later.

The conductive layer 37 is provided on the first surface of the semiconductor film 51. The conductive layer 37 functions as, for example, a columnar contact. The conductive layer 37 includes, for example, tungsten. The conductive layer 38 is provided on the first surface of the conductive layer 37. The conductive layer 38 functions as, for example, the contact CV. The conductive layer 38 includes, for example, tungsten. With the above configuration, the conductive layers 37 and 38 connect the semiconductor film 51 and the conductive layer 36. One conductive layer 37 and one conductive layer 38 are connected to one conductive layer 36 in each of the spaces divided by the members SLT and SHE.

The member SLT divides, for example, the conductive layers 30, 33, and 35 and the plurality of conductive layers 34. In other words, the member SLT penetrates the conductive layers 30, 33, and 35 and the plurality of conductive layers 34. The conductor LI in the member SLT is provided along the member SLT. The first surface of the conductor LI is located between the conductive layer 35 and the conductive layer 36, for example. The second surface of the conductor LI is in contact with the semiconductor layer 31a. The conductor LI includes, for example, tungsten. The spacer SP is provided between the conductor LI and a set of the conductive layer 30, the semiconductor layer 31a, the conductive layers 33 and 35, and the plurality of conductive layers 34. In other words, the side surface of the conductor LI is covered with the spacer SP. The conductor LI and a set of the conductive layers 33 and 35, and the plurality of conductive layers 34 are separated and electrically insulated by the spacer SP. The spacer SP includes, for example, silicon oxide. Although not illustrated in FIG. 6, the conductor LI may include a barrier metal. That is, the conductor LI may have a structure in which the barrier metal covers the second surface and the side surface of the conductive member including metal such as tungsten, for example. Further, the conductor LI may be formed of a semiconductor member, or may have a structure in which the entire member SLT is embedded by an insulator of the spacer SP.

A portion where each of the plurality of memory pillars MP intersects the conductive layer 33 functions as the selection transistor ST2. A portion where each of the plurality of memory pillars MP intersects each of the plurality of conductive layers 34 functions as the memory cell transistor MT. A portion where each of the plurality of memory pillars MP intersects the conductive layer 35 functions as the selection transistor ST1.

Although not illustrated in FIG. 6, in the present embodiment, a case where an insulator 46 is provided between the memory pillar MP and each of the conductive layers 33, 34, and 35, and the first surface and the second surface of each of the conductive layers 33, 34, and 35, and the side surface of the spacer SP are covered with the insulator 46 will be described.

### 1.1.6.3 Cross-Sectional Structure of Memory Pillar

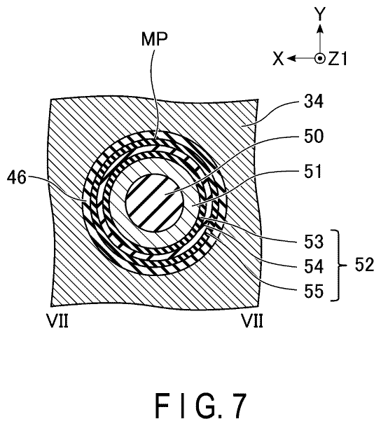

A cross-sectional structure of the memory pillar MP will be described with reference to FIG. 7. FIG. 7 is a cross-sectional view taken along line VII-VII of FIG. 6, illustrating an example of a cross-sectional structure of the memory pillar MP.

As illustrated in FIG. 7, the stacked film 52 includes, for example, a tunnel insulating film 53, an insulating film 54, and a block insulating film 55. The tunnel insulating film 53 covers the side surface of the semiconductor film 51 except for the portion where the semiconductor film 51 and the semiconductor layer 31a are in contact with each other. The insulating film 54 covers the side surface of the tunnel insulating film 53. The block insulating film 55 covers the side surface of the insulating film 54. The insulator 46 covers the side surface of the block insulating film 55. The insulator 46 functions as the block insulating film of the memory cell transistor MT together with the block insulating film 55. The conductive layer 34 covers the side surface of the insulator 46. The tunnel insulating film 53 and the block insulating film 55 include, for example, silicon oxide. The insulating film 54 includes, for example, silicon nitride. The insulator 46 includes, for example, aluminum oxide.

In the above configuration, the semiconductor film 51 functions as a channel of each of the memory cell transistors MT0 to MT7 and the selection transistors ST1 and ST2. Further, the insulating film 54 has a function to store a charge of an amount corresponding to data stored in the memory cell transistor MT. That is, the insulating film 54 functions as a charge storage layer of the memory cell transistor MT. The semiconductor memory device 3 causes a current to flow between the source line SL and the bit line BL via the memory pillar MP and the conductive layers 37 and 38 by turning on each of the memory cell transistors MT0 to MT7 and the select transistors ST1 and ST2.

### 1.1.7 Overall Cross-Sectional Structure of Semiconductor Memory Device

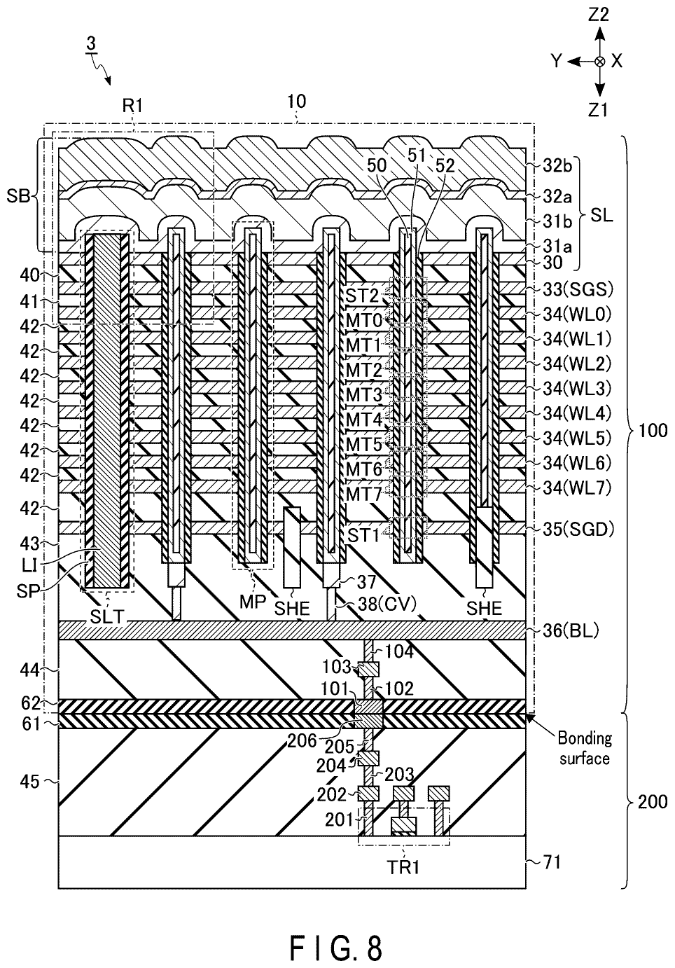

An overall cross-sectional structure of the semiconductor memory device 3 will be described with reference to FIG. 8. FIG. 8 is a cross-sectional view illustrating an example of a cross-sectional structure of the semiconductor memory device 3. FIG. 8 illustrates a cross-sectional structure of a part (a region corresponding to the memory region MR of the array chip 100 and the memory region MR of the circuit chip 200) of the semiconductor memory device 3.

### 1.1.7.1 Circuit Chip

First, a cross-sectional structure of the circuit chip 200 will be described.

As illustrated in FIG. 8, the circuit chip 200 includes, for example, a semiconductor substrate 71, a plurality of conductive layers 201, 202, 203, 204, 205, and 206 constituting a part of the peripheral circuits, and insulating layers 45 and 61. The semiconductor substrate 71 is formed of, for example, a P-type semiconductor doped with impurities. Each of the plurality of conductive layers 201 to 206 functions as, for example, a columnar contact or wiring. FIG. 8 illustrates one conductive layer 203 of the plurality of conductive layers 203, one conductive layer 204 of the plurality of conductive layers 204, one conductive layer 205 of the plurality of conductive layers 205, and one conductive layer 206 of the plurality of conductive layers 206.

The insulating layer 45 is provided on the first surface of the semiconductor substrate 71. The insulating layer 45 includes, for example, silicon oxide. In the insulating layer 45, the plurality of conductive layers 201, 202, 203, 204, and 205 are provided.

The peripheral circuits are provided on the first surface of the semiconductor substrate 71. FIG. 8 illustrates a transistor TR1 as an example of a configuration included in the peripheral circuits. The transistor TR1 is included in the sense amplifier module 16, for example. The transistor TR1 includes a gate insulating film, a gate electrode, and a source and a drain (not illustrated) provided on the semiconductor substrate 71.

The conductive layer 201 is provided on the first surface of each of the gate electrode, the source, and the drain of the transistor TR1. The corresponding conductive layer 202 is provided on the first surface of each of the plurality of conductive layers 201.

The corresponding conductive layer 203 is provided on the first surface of each of the plurality of conductive layers 202.

The corresponding conductive layer 204 is provided on the first surface of each of the plurality of conductive layers 203.

The corresponding conductive layer 205 is provided on the first surface of each of the plurality of conductive layers 204. The first surface of each of the plurality of conductive layers 205 is provided so as to be flush with the first surface of the insulating layer 45.

The insulating layer 61 is provided on the first surface of each of the insulating layer 45 and the plurality of conductive layers 205. The insulating layer 61 includes, for example, silicon oxide.

The plurality of conductive layers 206 is provided in the same layer as the insulating layer 61. Each of the plurality of conductive layers 206 is connected to the first surface of the corresponding conductive layer 205. The first surface of each of the plurality of conductive layers 206 is provided so as to be flush with the first surface of the insulating layer 61. The conductive layer 206 includes, for example, copper. The plurality of conductive layers 206 functions as the plurality of bonding pads BP for electrically connecting the circuit chip 200 and the array chip 100.

### 1.1.7.2 Array Chip

Next, a cross-sectional structure of the array chip 100 will be described.

As illustrated in FIG. 8, the array chip 100 includes, for example, a plurality of conductive layers 101, 102, 103, and 104, and the memory cell array 10. Each of the plurality of conductive layers 101 to 104 functions as, for example, a columnar contact or wiring. FIG. 8 illustrates one conductive layer 101 of the plurality of conductive layers 101, one conductive layer 102 of the plurality of conductive layers 102, one conductive layer 103 of the plurality of conductive layers 103, and one conductive layer 104 of the plurality of conductive layers 104. The memory cell array 10 includes the conductive layer 30, the layer stack SB, the conductive layers 33 and 35, the plurality of conductive layers 34, 36, 37, and 38, the plurality of memory pillars MP, and the plurality of members SLT and SHE. The conductive layer 30 is disposed between a set of the conductive layers 33 and 35 and the plurality of conductive layers 34, and the layer stack SB, is separated from the conductive layers 33 and 35 and the plurality of conductive layers 34 in the Z2 direction, and is in contact with the semiconductor layer 31a.

In the array chip 100, an insulating layer 62 is provided on the first surface of the circuit chip 200. The insulating layer 62 includes, for example, silicon oxide.

The plurality of conductive layers 101 is provided in the same layer as the insulating layer 62. Each of the plurality of conductive layers 101 is connected to the first surface of the corresponding conductive layer 206. The second surface of each of the plurality of conductive layers 101 is provided so as to be flush with the second surface of the insulating layer 62. The conductive layer 101 includes, for example, copper. The plurality of conductive layers 101 functions as the plurality of bonding pads BP for electrically connecting the circuit chip 200 and the array chip 100. With the above configuration, the circuit chip 200 and the array chip 100 are electrically connected by the plurality of conductive layers 206 and 101.

The insulating layer 44 is provided on the second surface of each of the insulating layer 62 and the plurality of conductive layers 101. In the insulating layer 44, the plurality of conductive layers 102 to 104 is provided.

The corresponding conductive layer 102 is provided on the second surface of each of the plurality of conductive layers 101. The corresponding conductive layer 103 is provided on the second surface of each of the plurality of conductive layers 102. The corresponding conductive layer 104 is provided on the second surface of each of the plurality of conductive layers 103. The second surface of each of the plurality of conductive layers 104 is connected to the conductive layer 36. With the above configuration, the conductive layer 36 and the transistor TR1 can be connected. That is, the bit line BL of the memory cell array 10 and the sense amplifier module 16 are electrically connected.

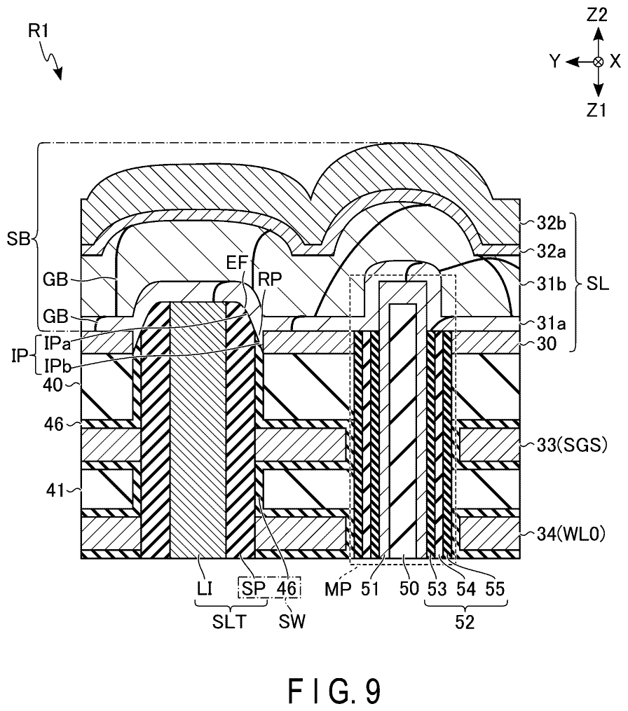

Next, details of cross-sectional structures of the layer stack SB and a vicinity of the layer stack SB will be described. FIG. 9 is an enlarged cross-sectional view of a partial region (region R1) including the layer stack SB of FIG. 8.

As illustrated in FIG. 9, the insulator 46 is provided between the block insulating film 55 and the conductive layer 33, between the block insulating film 55 and the conductive layer 34, and between the block insulating film 55 and the conductive layer 35 (not illustrated). The insulator 46 is provided on the first surface and the second surface of the conductive layer 33, on the first surface and the second surface of the conductive layer 34, and on the first surface and the second surface of the conductive layer 35 (not illustrated). The insulator 46 covers the side surface of the spacer SP except for a portion where the spacer SP and the conductive layer 33 are in contact with each other, a portion where the spacer SP and the conductive layer 34 are in contact with each other, and a portion where the spacer SP and the conductive layer 35 are in contact with each other (not illustrated). Hereinafter, a structure including the spacer SP covering the side surface of the conductor LI in the Y direction and the insulator 46 covering the side surface of the spacer SP in the Y direction is referred to as an “insulator SW”. The insulator SW covers the side surface of the conductor LI in the Y direction. In addition, a structure including the conductor LI and the insulator SW covering the side surface of the conductor LI in the Y direction is also referred to as a “member SLT”.

End portions of the spacer SP and the insulator 46 in the Z2 direction are etched. More specifically, a corner on the side not in contact with the conductor LI of the end portion of the spacer SP in the Z2 direction is removed. That is, the end surface of the spacer SP in the Z2 direction has an inclined portion IPa on the side not in contact with the conductor LI. The end portion of the insulator 46 in the Z2 direction is etched to the first surface of the conductive layer 30. That is, the end surface of the insulator 46 in the Z2 direction has an inclined portion IPb along the inclined portion IPa. The inclined portion IPb reaches the first surface of the conductive layer 30. In other words, an end surface EF of the insulator SW in the Z2 direction has an inclined portion IP on the side not in contact with the conductor LI. The inclined portion IP includes the inclined portion IPa and the inclined portion IPb. A recess portion RP exists between the inclined portion IP and the conductive layer 30. An angle of the inclined portion IP with respect to the side surface of the conductive layer 30 is an acute angle. The inclined portion IP is in contact with the semiconductor layer 31a. Further, the inclined portion IP is in contact with the conductive layer 30 at a position below the upper surface of the conductive layer 30 in the Z2 direction.

In the Z2 direction, the semiconductor layer 31a is provided on each of the conductive layer 30, the semiconductor film 51, the tunnel insulating film 53, the insulating film 54, the block insulating film 55, the conductor LI, the spacer SP, and the insulator 46. The semiconductor layer 31a covers an end portion (an end surface and a side surface of the end portion) of the semiconductor film 51 in the Z2 direction. The semiconductor layer 31a covers an end portion of the member SLT in the Z2 direction (an end surface of the conductor LI in the Z2 direction, an end surface of the spacer SP in the Z2 direction, and an end surface of the insulator 46 in the Z2 direction). The recess portion RP is embedded by the semiconductor layer 31a.

The semiconductor layer 31a includes a plurality of grains (crystal grains). The solid line in the semiconductor layer 31a in FIG. 9 schematically represents a grain boundary GB. A portion surrounded by the two grain boundaries GB corresponds to a grain.

In the Z2 direction, the semiconductor layer 31b is provided on the semiconductor layer 31a. The semiconductor layer 31b includes a plurality of grains. The solid line in the semiconductor layer 31b in FIG. 9 schematically represents the grain boundary GB. A portion surrounded by the two grain boundaries GB corresponds to a grain.

As illustrated in FIG. 9, the grain boundary GB of the semiconductor layer 31a and the grain boundary GB of the semiconductor layer 31b are not connected. That is, the grain boundary GB of the semiconductor layer 31a and the grain boundary GB of the semiconductor layer 31b are discontinuous. Further, a grain diameter (grain size) of the semiconductor layer 31a is different from a grain diameter of the semiconductor layer 31b. For example, the grain diameter of the semiconductor layer 31a is smaller than the grain diameter of the semiconductor layer 31b. The grain diameters of the semiconductor layers 31a and 31b vary depending on, for example, a method of forming the semiconductor layers 31a and 31b, amounts of impurities implanted into the semiconductor layers 31a and 31b, types of the impurities implanted into the semiconductor layers 31a and 31b, film thicknesses of the semiconductor layers 31a and 31b, or the like. For example, the larger the film thickness, the larger the grain diameters of the semiconductor layers 31a and 31b.

Note that an oxide film may be provided between the semiconductor layer 31a and the semiconductor layer 31b.

In the Z2 direction, the conductive layer 32a is provided on the semiconductor layer 31b. In the Z2 direction, the conductive layer 32b is provided on the conductive layer 32a.

### 1.2 Method of Manufacturing Semiconductor Memory Device

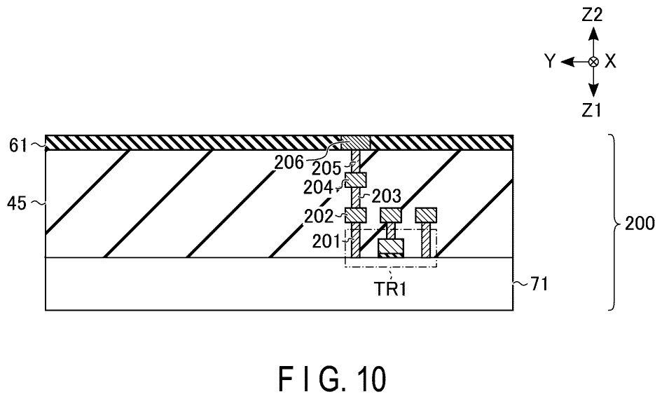

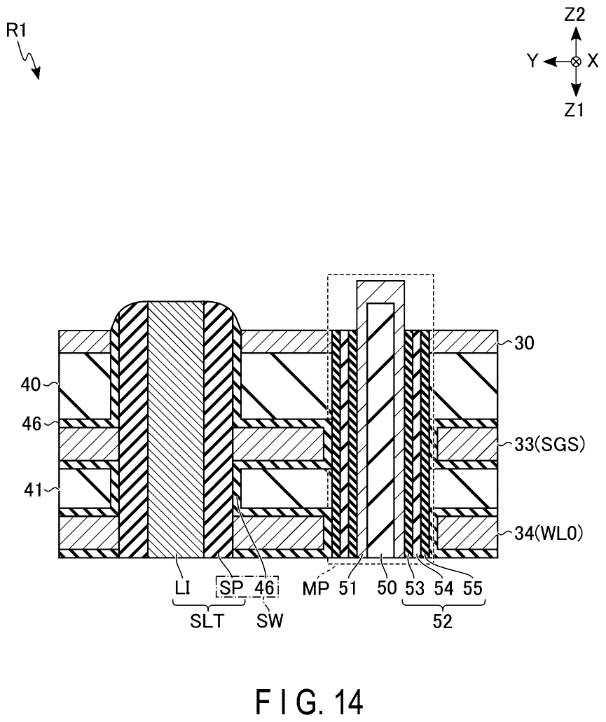

A method of manufacturing the semiconductor memory device 3 will be described with reference to FIGS. 10 to 17. FIGS. 10 to 17 are cross-sectional views for describing an example of a method of manufacturing the semiconductor memory device 3. FIGS. 10 to 13 illustrate cross-sectional views of a region corresponding to FIG. 8. FIGS. 14 to 17 illustrate cross-sectional views of a region corresponding to FIG. 9.

First, as illustrated in FIG. 10, the transistor TR1 included in the peripheral circuits, the plurality of conductive layers 201 to 206, and the insulating layers 45 and 61 are formed on the first surface of the semiconductor substrate 71. That is, the circuit chip 200 is formed.

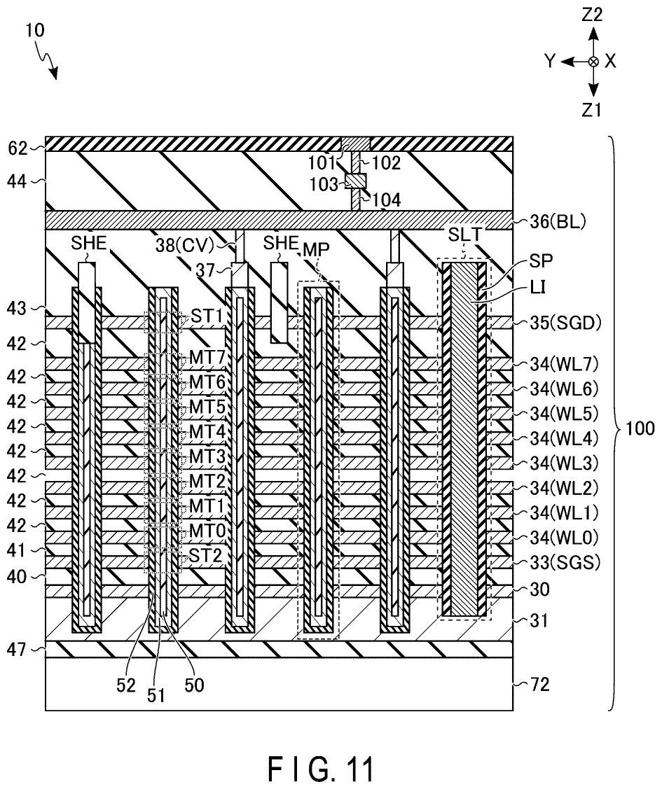

Next, as illustrated in FIG. 11, the insulating layer 47, the semiconductor layer 31, the conductive layers 30, 33, and 35, the plurality of conductive layers 34, 36, 37, 38, and 101 to 104, the insulating layers 40, 41, 43, 44, and 62, the plurality of insulating layers 42, the plurality of memory pillars MP, and the plurality of members SLT and SHE are formed on the first surface of the semiconductor substrate 72 formed of the P-type semiconductor doped with impurities. That is, the structure corresponding to the array chip 100 is formed. The semiconductor layer 31 includes, for example, doped polysilicon doped with an N-type impurity. Note that the semiconductor layer 31 and the insulating layers 47 and 62 are entirely formed on the first surface of the semiconductor substrate 72.

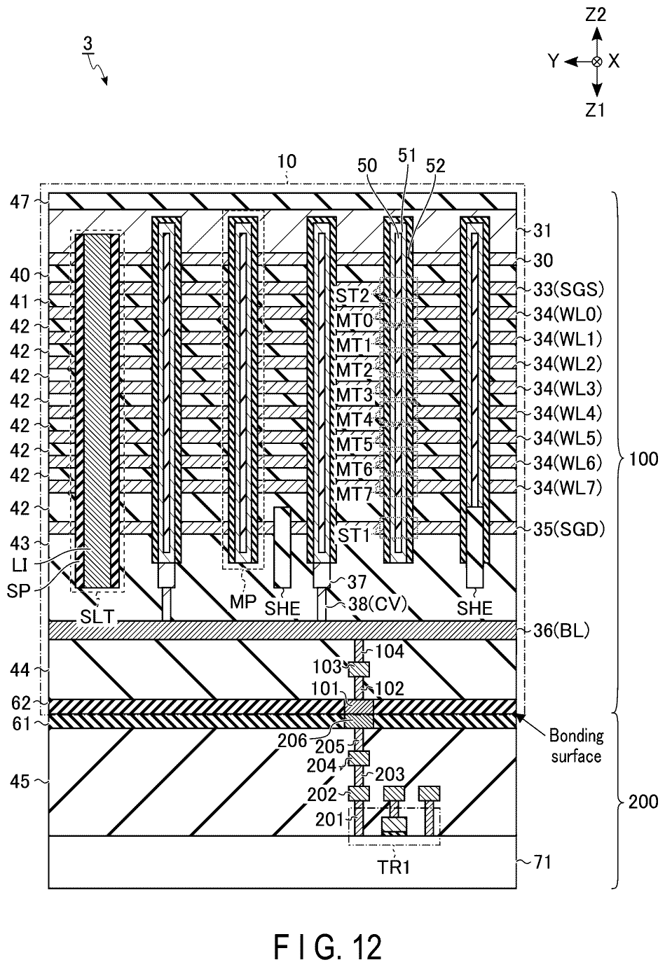

Next, as illustrated in FIG. 12, the structure corresponding to the circuit chip 200 and the structure corresponding to the array chip 100 are bonded together by bonding processing. More specifically, the plurality of conductive layers 206 that functions as the bonding pad BP in the circuit chip 200 and the plurality of conductive layers 101 that functions as the bonding pad BP in the array chip 100 are disposed to face each other. Further, the facing bonding pads BP are bonded to each other by heat treatment. Thereafter, the semiconductor substrate 72 is removed by, for example, chemical mechanical polishing (CMP).

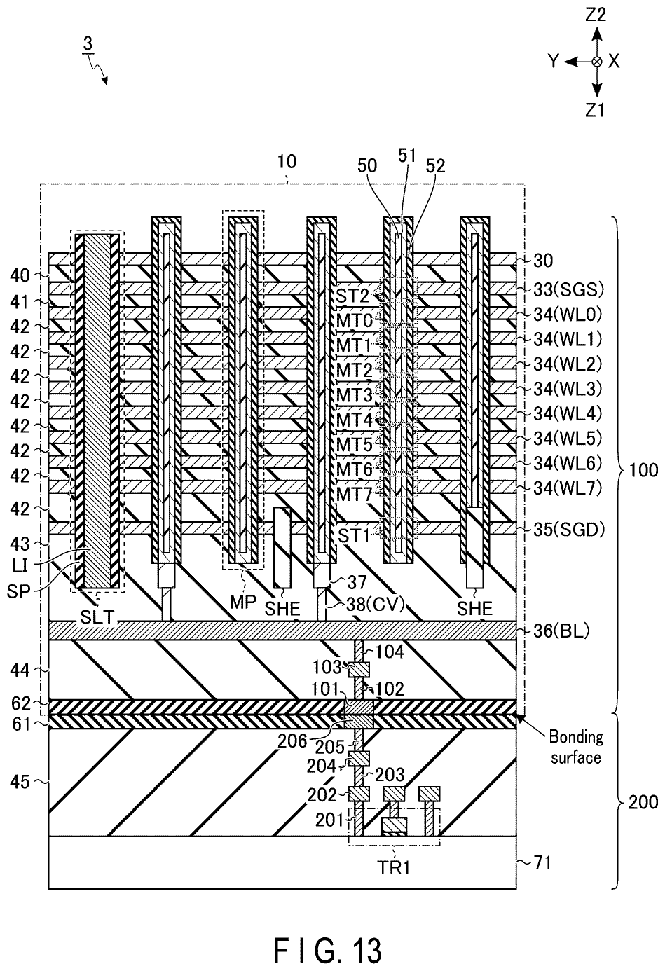

Next, as illustrated in FIG. 13, the insulating layer 47 and the semiconductor layer 31 in the portion corresponding to the memory cell array 10 are removed. As a result, the end portion of each of the plurality of memory pillars MP and the member SLT in the Z2 direction is exposed. Since a resist mask is formed in the region other than the portion corresponding to the memory cell array 10, the insulating layer 47 and the semiconductor layer 31 remain without being removed.

Next, as illustrated in FIG. 14, the stacked film 52 is removed. For example, the stacked film 52 is removed in the order of the block insulating film 55, the insulating film 54, and the tunnel insulating film 53.

First, the block insulating film 55 is removed. For example, the block insulating film 55 is processed by isotropic etching by wet etching using buffered hydrofluoric acid (BHF). As a result, the block insulating film 55 above the second surface of the conductive layer 30 is removed at the end portion of the memory pillar MP in the Z2 direction. At this time, the end portions of the spacer SP and the insulator 46 in the Z2 direction are also slightly removed.

Next, the insulating film 54 is removed. For example, the insulating film 54 is processed by isotropic etching by wet etching using phosphoric acid. As a result, the insulating film 54 above the second surface of the conductive layer 30 is removed at the end portion of the memory pillar MP in the Z2 direction.

Next, the tunnel insulating film 53 is removed. For example, the tunnel insulating film 53 is processed by isotropic etching by chemical dry etching (CDE). As a result, the tunnel insulating film 53 above the second surface of the conductive layer 30 is removed at the end portion of the memory pillar MP in the Z2 direction. At this time, the end portions of the spacer SP and the insulator 46 in the Z2 direction are also slightly removed.

By removing the block insulating film 55, removing the insulating film 54, and removing the tunnel insulating film 53, the end portion of the semiconductor film 51 of the memory pillar MP in the Z2 direction is exposed. That is, a channel is exposed. As a result, the second surface of the memory pillar MP has a step. Further, as described above, the end portions of the spacer SP and the insulator 46 in the Z2 direction are slightly removed. Since the member SLT has the structure in which the side surface of the conductor LI is covered with the spacer SP and the insulator 46, the corner on the side not in contact with the conductor LI of the end portion of the spacer SP in the Z2 direction is obliquely etched, and the end portion of the insulator 46 in the Z2 direction is obliquely etched along the portion where the spacer SP is etched.

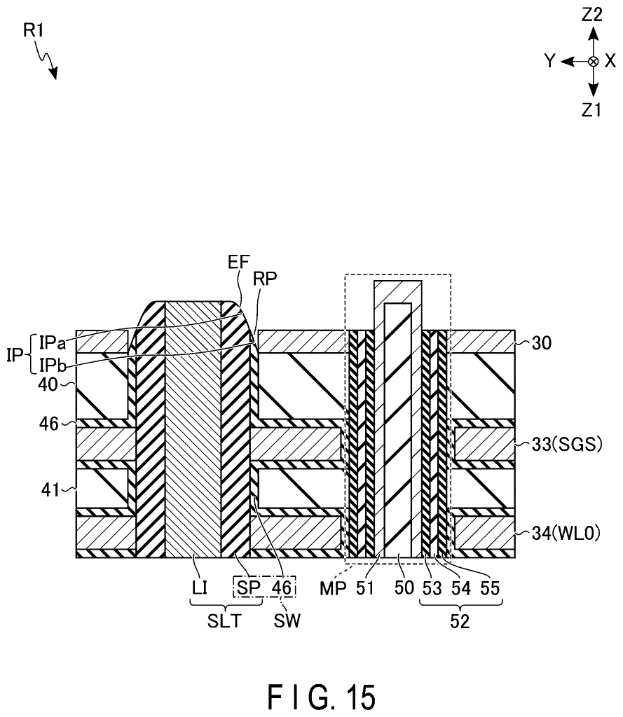

After the removal of the stacked film 52, isotropic etching by wet etching using diluted hydrofluoric acid (DHF) is performed, for example, in order to eliminate resistance at an interface of the conductive layer 30. As a result, a natural oxide film on the second surface of the conductive layer 30 is removed. At this time, as illustrated in FIG. 15, the end portions of the spacer SP and the insulator 46 in the Z2 direction are also etched. Since the member SLT has the structure in which the side surface of the conductor LI is covered with the spacer SP and the insulator 46, the inclined portion IPa is formed on the side not in contact with the conductor LI of the end surface of the spacer SP in the Z2 direction. The inclined portion IPb along the inclined portion IPa is formed on the end surface of the insulator 46 in the Z2 direction. The inclined portion IPb reaches the first surface of the conductive layer 30. In other words, the inclined portion IP is formed on the side not in contact with the conductor LI of the end surface EF of the insulator SW in the Z2 direction. As a result, the recess portion RP is formed between the inclined portion IP and the conductive layer 30. The angle of the inclined portion IP with respect to the side surface of the conductive layer 30 is an acute angle. In other words, the recess portion RP falls at an acute angle.

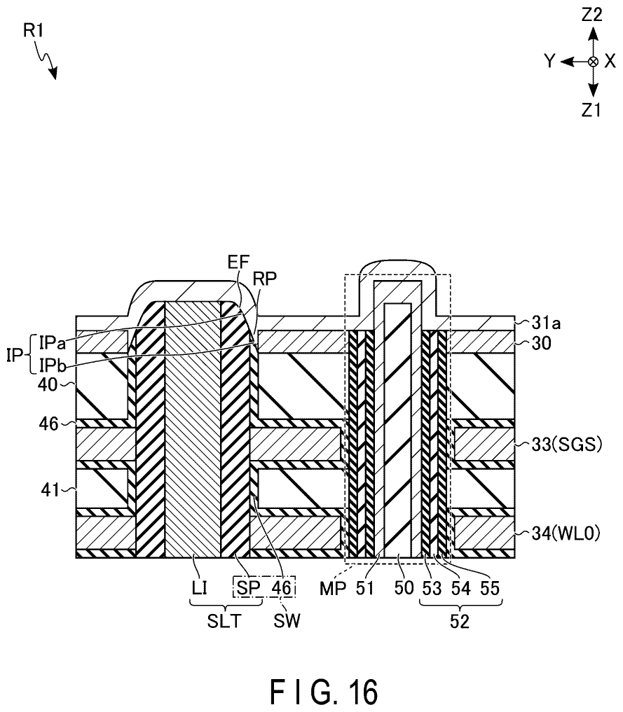

Next, as illustrated in FIG. 16, the semiconductor layer 31a is formed. For example, the semiconductor layer 31a is formed by low pressure chemical vapor deposition (LP-CVD) or plasma enhanced chemical vapor deposition (PE-CVD). For example, amorphous silicon is deposited as the semiconductor layer 31a. As a result, the semiconductor layer 31a is formed on the second surface of each of the conductive layer 30, the plurality of memory pillars MP, and the plurality of members SLT. Specifically, in the Z2 direction, the semiconductor layer 31a is formed on each of the conductive layer 30, the semiconductor film 51, the tunnel insulating film 53, the insulating film 54, the block insulating film 55, the conductor LI, the spacer SP, and the insulator 46. By using LP-CVD or PE-CVD having a relatively high coverability, the recess portion RP that falls at an acute angle is also embedded by the semiconductor layer 31a.

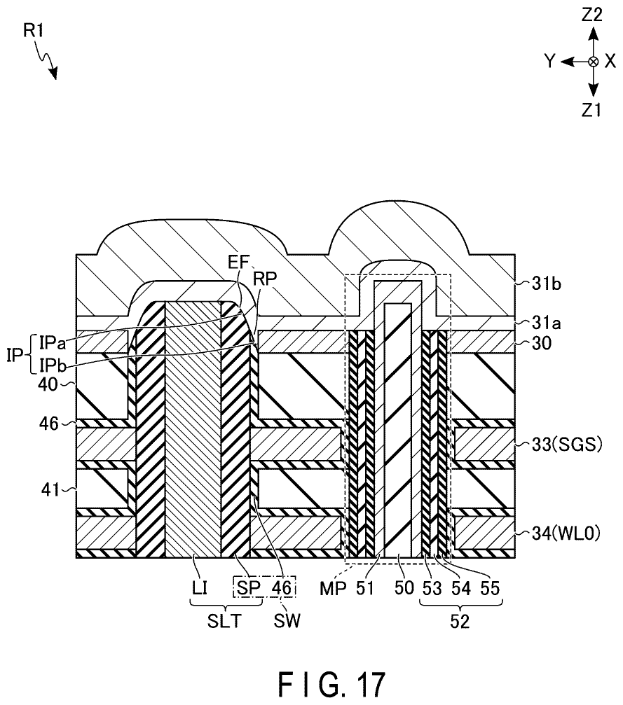

Next, as illustrated in FIG. 17, the semiconductor layer 31b is formed. For example, the semiconductor layer 31b is formed by physical vapor deposition (PVD). For example, amorphous silicon is deposited as the semiconductor layer 31b. As a result, the semiconductor layer 31b is formed on the second surface of the semiconductor layer 31a. Note that the semiconductor layer 31b may be formed by a film forming method other than PVD. For example, the semiconductor layer 31b may be formed by LP-CVD or PE-CVD.

Next, for example, impurities are introduced into the semiconductor layers 31a and 31b by ion implantation. The impurities include, for example, phosphorus.

Next, heat treatment is performed on the semiconductor layers 31a and 31b by laser annealing, for example. A laser having a relatively long wavelength is used to instantaneously increase heat to activate the impurities. As a result, the impurities are diffused into the semiconductor layers 31a and 31b. Further, the grains of the formed semiconductor layers 31a and 31b (amorphous silicon) move and grow by heat, and are finally crystallized and modified into polysilicon.

In a case where a method of forming the semiconductor layers 31a and 31b is different, manner of grain growth of amorphous silicon is different. Further, in a case where the amount of impurities implanted into the semiconductor layers 31a and 31b, the types of impurities implanted into the semiconductor layers 31a and 31b, the film thicknesses of the semiconductor layers 31a and 31b, or the like is different, the manner of grain growth of amorphous silicon is different. Therefore, the grain boundary of the semiconductor layer 31a and the grain boundary of the semiconductor layer 31b are discontinuous. Further, the grain diameter of the semiconductor layer 31a and the grain diameter of the semiconductor layer 31b are also different. For example, the larger the film thickness, the larger the grain diameters of the semiconductor layers 31a and 31b. In a case where the film thickness of the semiconductor layer 31b is larger than that of the semiconductor layer 31a, the grain diameter of the semiconductor layer 31a is smaller than that of the semiconductor layer 31b.

After the heat treatment, for example, isotropic etching by wet etching using DHF is performed in order to eliminate resistance at the interface of the semiconductor layer 31b. As a result, the natural oxide film on the second surface of the semiconductor layer 31b is removed.

Next, the conductive layer 32a is formed. For example, the conductive layer 32a is formed by PVD. As the conductive layer 32a, for example, titanium or titanium nitride is deposited. As a result, the conductive layer 32a is formed on the second surface of the semiconductor layer 31b.

Next, the conductive layer 32b is formed. For example, the conductive layer 32b is formed by PVD. As the conductive layer 32b, for example, tungsten is deposited. As a result, the conductive layer 32b is formed on the second surface of the conductive layer 32a, and the structure illustrated in FIG. 9 is formed.

The semiconductor memory device 3 is formed by the above-described manufacturing process. Note that the above-described manufacturing process is merely an example, and the manufacturing process of the semiconductor memory device 3 is not limited thereto. For example, other processes may be inserted between the manufacturing processes, or some processes may be omitted or integrated. A process of forming an oxide film between the semiconductor layer 31a and the semiconductor layer 31b may be inserted between the process of forming the semiconductor layer 31a and the process of forming the semiconductor layer 31b. Further, each manufacturing process may be shuffled within the possible range.

### 1.3 Effects According to Present Embodiment

In the structure in which the source line SL having the layer stack of polysilicon, barrier metal, and metal is formed on the uppermost conductive layer after the array chip 100 and the circuit chip 200 are bonded, the stacked film 52 of the memory pillar MP and the natural oxide film on the conductive layer are removed before the formation of the amorphous silicon. At this time, there is a possibility that a part of the insulator SW of the member SLT is etched, and the recess portion that falls at an acute angle is formed between the member SLT and the conductive layer. In a case where such a recess portion is formed, there is a possibility that a portion that is not embedded with amorphous silicon is generated in the recess portion in a process of forming amorphous silicon. In a case where there is a portion that is not embedded with amorphous silicon in the recess portion, in a process of removing the natural oxide film before the formation of the barrier metal and the metal film, there is a possibility that an etching solution goes into the portion of the recess portion where the amorphous silicon is not embedded by wet etching, and the insulator SW of the member SLT is dissolved. In a case where there is a dissolved portion in the insulator SW, there is a possibility that a metal film is formed in the dissolved portion of the insulator SW in a process of forming the metal film, and a short circuit occurs between the source line SL and the select gate line SGS.

In contrast, in the present embodiment, two semiconductor layers are formed as the semiconductor layers covering the semiconductor film 51 (channel) and the member SLT. For example, the semiconductor layers 31a and 31b are formed. Since the two semiconductor layers are formed, the coverability for the recess portion RP that falls at an acute angle is improved as compared with a case where one semiconductor layer is formed. Therefore, the recess portion RP is embedded by the semiconductor layer 31a (amorphous silicon). As a result, it is possible to suppress dissolution of the insulator SW due to wet etching in the process of removing the natural oxide film before formation of barrier metal and metal, as compared with the case where one semiconductor layer is formed. Therefore, it is possible to suppress occurrence of the short circuit between the source line SL and the select gate line SGS. Therefore, a yield can be improved. Note that three or more semiconductor layers may be formed as the semiconductor layers covering the semiconductor film 51, and a similar effect can be obtained in a case where three or more semiconductor layers are formed.

In the present embodiment, the semiconductor layer 31a is formed by using, for example, LP-CVD or PE-CVD. Since LP-CVD or PE-CVD has a relatively high coverability, the coverability for the recess portion RP that falls at an acute angle is improved as compared with a case where the semiconductor layer 31a is formed by a film forming method other than LP-CVD or PE-CVD. Therefore, the recess portion RP is embedded by the semiconductor layer 31a (amorphous silicon). Therefore, a yield can be improved.

In addition, in a case where the grain boundary of the semiconductor layer 31a and the grain boundary of the semiconductor layer 31b are connected to each other, in the process of removing the natural oxide film before the formation of the barrier metal and metal, there is a possibility that the etching solution reaches the insulator SW through the grain boundary by wet etching, and a hole is formed in the insulator SW to form a pinhole.

In contrast, in the present embodiment, the grain boundary of the semiconductor layer 31a and the grain boundary of the semiconductor layer 31b are discontinuous. For example, the semiconductor layer 31a is formed using LP-CVD or PE-CVD. The semiconductor layer 31b is formed by PVD. That is, the method of forming the semiconductor layers 31a and 31b is different. The grain boundary of the semiconductor layer 31a and the grain boundary of the semiconductor layer 31b are discontinuous because the manner of grain growth varies depending on the film forming method. Further, the grain diameter of the semiconductor layer 31a and the grain diameter of the semiconductor layer 31b are also different. Therefore, as compared with the case where the grain boundary of the semiconductor layer 31a and the grain boundary of the semiconductor layer 31b are connected, it is possible to suppress formation of pinholes in the insulator SW in the process of removing the natural oxide film before formation of the barrier metal and metal. Therefore, a yield can be improved. Note that the manner of grain growth is different depending on the amounts of impurities implanted into the semiconductor layers 31a and 31b, the types of impurities implanted into the semiconductor layers 31a and 31b, the film thicknesses of the semiconductor layers 31a and 31b, or the like. Therefore, similar effects can be obtained even in the case where the amounts of impurities, the types of impurities, the film thicknesses, or the like of the semiconductor layers 31a and 31b are different.

### 2. Second Embodiment

A semiconductor memory device according to a second embodiment will be described. In a semiconductor memory device 3A according to the present embodiment, a structure of a layer stack SB is different from that of the first embodiment. Hereinafter, differences from the first embodiment will be mainly described.

### 2.1 Overall Cross-Sectional Structure of Semiconductor Memory Device

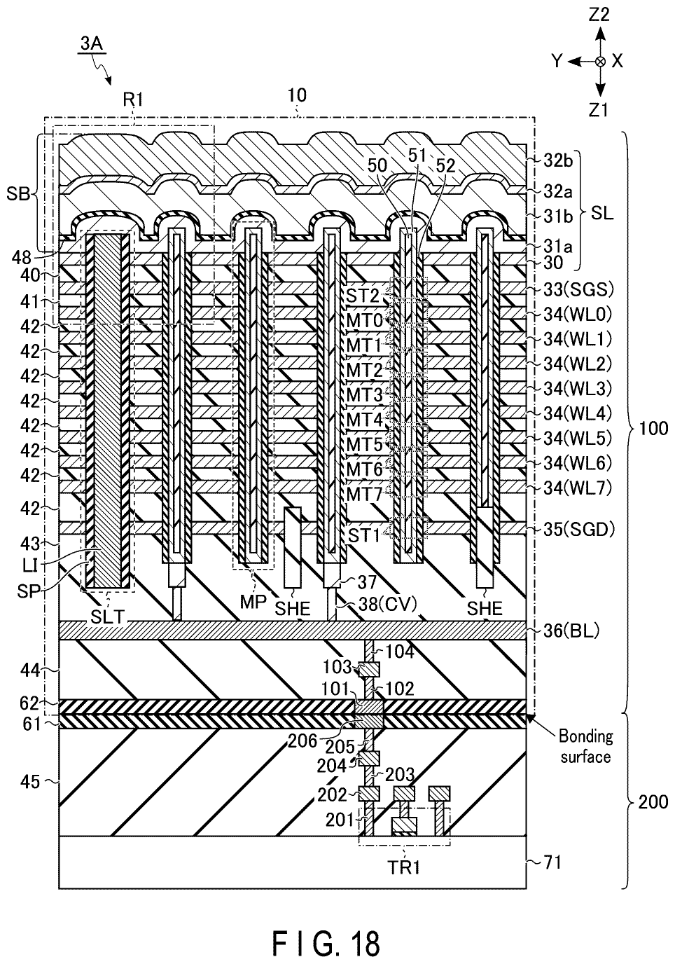

An overall cross-sectional structure of the semiconductor memory device 3A will be described with reference to FIG. 18. FIG. 18 is a cross-sectional view illustrating an example of a cross-sectional structure of the semiconductor memory device 3A. FIG. 18 illustrates a cross-sectional structure of a part (a region corresponding to the memory region MR of the array chip 100 and the memory region MR of the circuit chip 200) of the semiconductor memory device 3A.

As illustrated in FIG. 18, the memory cell array 10 further includes an insulating layer 48 in addition to the configuration of FIG. 8 described in the first embodiment. More specifically, a layer stack SB has a structure in which the insulating layer 48 is further provided between a semiconductor layer 31a and a semiconductor layer 31b. The cross-sectional structure other than the layer stack SB is similar to that in FIG. 8 described in the first embodiment.

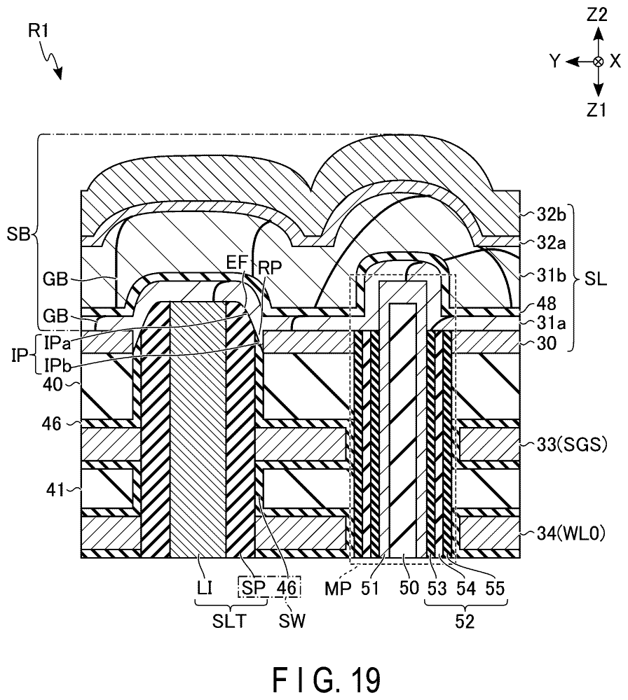

Next, details of cross-sectional structures of the layer stack SB and a vicinity of the layer stack SB will be described. FIG. 19 is an enlarged cross-sectional view of a partial region (region R1) including the layer stack SB of FIG. 18.

As illustrated in FIG. 19, the insulating layer 48 is provided on the semiconductor layer 31a in a Z2 direction. The insulating layer 48 includes, for example, silicon oxide or silicon nitride. That is, the insulating layer 48 is, for example, an oxide film or a nitride film. In the Z2 direction, the semiconductor layer 31b is provided on the insulating layer 48.

As illustrated in FIG. 19, a grain boundary GB of the semiconductor layer 31a and a grain boundary GB of the semiconductor layer 31b are divided by the insulating layer 48. As a result, the grain boundary GB of the semiconductor layer 31a and the grain boundary GB of the semiconductor layer 31b are not connected. That is, the grain boundary GB of the semiconductor layer 31a and the grain boundary GB of the semiconductor layer 31b are discontinuous. Further, a grain diameter of the semiconductor layer 31a is different from a grain diameter of the semiconductor layer 31b. For example, the grain diameter of the semiconductor layer 31a is smaller than that of the semiconductor layer 31b.

### 2.2 Method of Manufacturing Semiconductor Memory Device

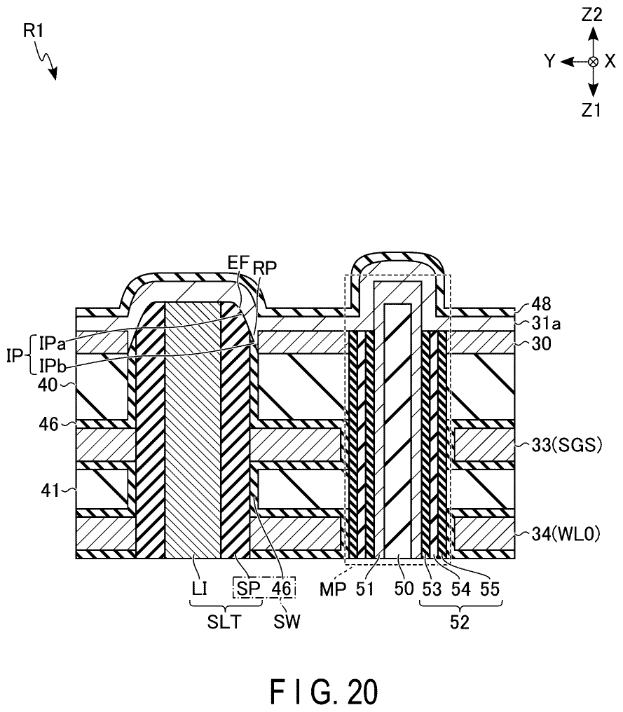

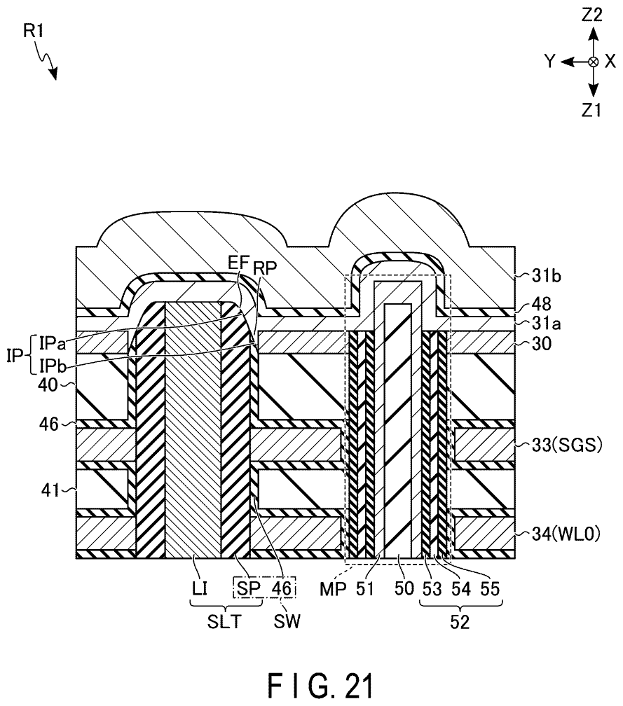

A method of manufacturing the semiconductor memory device 3A will be described with reference to FIGS. 20 and 21. FIGS. 20 and 21 are cross-sectional views for describing an example of a method of manufacturing the semiconductor memory device 3A. FIGS. 20 and 21 illustrate cross-sectional views of a region corresponding to FIG. 19.

First, in a similar manner to the first embodiment, processes up to the process of removing the natural oxide film on the second surface of the conductive layer 30 after removal of the stacked film 52 are performed.

Next, the semiconductor layer 31a is formed. For example, the semiconductor layer 31a is formed by PVD. For example, amorphous silicon is deposited as the semiconductor layer 31a. As a result, in the Z2 direction, the semiconductor layer 31a is formed on each of the conductive layer 30, the semiconductor film 51, the tunnel insulating film 53, the insulating film 54, the block insulating film 55, the conductor LI, the spacer SP, and the insulator 46. Note that the semiconductor layer 31a may be formed by a film forming method other than PVD. For example, the semiconductor layer 31a may be formed by LP-CVD or PE-CVD.

Next, heat treatment is performed on the semiconductor layer 31a by laser annealing, for example. As a result, a grain of the semiconductor layer 31a (amorphous silicon) moves, and a recess portion RP is embedded by the semiconductor layer 31a.

Next, as illustrated in FIG. 20, the insulating layer 48 is formed on the semiconductor layer 31a in the Z2 direction. For example, a structure in which the semiconductor layer 31a is formed is opened to an atmosphere in a clean room. As a result, the insulating layer 48 is formed. A thickness of the insulating layer 48 is, for example, about 1 nm.

Note that, as the insulating layer 48, an oxide film may be formed not by a natural oxide film but by radical oxidation by plasma. Further, as the insulating layer 48, a nitride film may be formed by radical nitriding by plasma.

Next, as illustrated in FIG. 21, the semiconductor layer 31b is formed by, for example, PVD. For example, amorphous silicon is deposited as the semiconductor layer 31b. As a result, the semiconductor layer 31b is formed on the insulating layer 48 in the Z2 direction. Note that the semiconductor layer 31b may be formed by a film forming method other than PVD. For example, the semiconductor layer 31b may be formed by LP-CVD or PE-CVD.

Thereafter, similarly to the first embodiment, processes of introducing impurities, heat treatment, removing the natural oxide film on the second surface of the semiconductor layer 31b, forming the conductive layer 32a, and forming the conductive layer 32b are performed. In the heat treatment process, for example, heat treatment is performed by laser annealing, and grains of the formed semiconductor layers 31a and 31b (amorphous silicon) move and grow by heat. Because of the presence of the insulating layer 48 between the semiconductor layer 31a and the semiconductor layer 31b, the growth of grains of amorphous silicon ceases at the insulating layer 48. Therefore, the grain diameter of the semiconductor layer 31a and the grain diameter of the semiconductor layer 31b are different.

### 2.3 Effects According to Present Embodiment

In the present embodiment, for example, amorphous silicon is deposited as the semiconductor layer 31a by PVD, and then heat treatment by laser annealing is performed. The grains of the amorphous silicon move and grow by heat. Therefore, as the grain of the semiconductor layer 31a (amorphous silicon) moves, the recess portion RP is embedded by the amorphous silicon. As a result, similarly to the first embodiment, it is possible to suppress dissolution of the insulator SW due to wet etching in the process of removing the natural oxide film before the formation of barrier metal and metal. Therefore, a yield can be improved.

Furthermore, in the present embodiment, for example, the insulating layer 48 is provided between the semiconductor layer 31a and the semiconductor layer 31b. As a result, the semiconductor layer 31a and the semiconductor layer 31b are divided by the insulating layer 48. That is, the grain boundary of the semiconductor layer 31a and the grain boundary of the semiconductor layer 31b are discontinuous. Also, grain growth in the semiconductor layers 31a and 31b (amorphous silicon) stops at the insulating layer 48. Therefore, the grain diameter of the semiconductor layer 31a and the grain diameter of the semiconductor layer 31b are different. As a result, similarly to the first embodiment, it is possible to suppress formation of pinholes in the insulator SW in the process of removing the natural oxide film before the formation of barrier metal and metal. Therefore, a yield can be improved.

### 3. Third Embodiment

A semiconductor memory device according to a third embodiment will be described. In a semiconductor memory device 3B according to the present embodiment, a structure of a layer stack SB is different from that of the first embodiment. Hereinafter, differences from the first embodiment will be mainly described.

### 3.1 Overall Cross-Sectional Structure of Semiconductor Memory Device

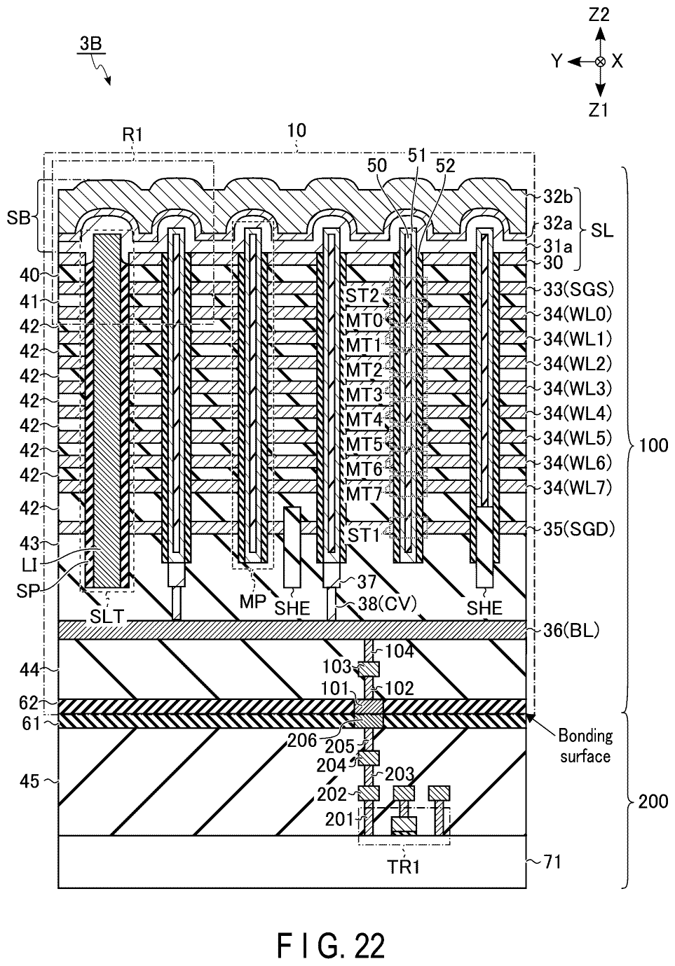

An overall cross-sectional structure of the semiconductor memory device 3B will be described with reference to FIG. 22. FIG. 22 is a cross-sectional view illustrating an example of a cross-sectional structure of the semiconductor memory device 3B. FIG. 22 illustrates a cross-sectional structure of a part (a region corresponding to the memory region MR of the array chip 100 and the memory region MR of the circuit chip 200) of the semiconductor memory device 3B.

As illustrated in FIG. 22, in the memory cell array 10, the semiconductor layer 31b is eliminated from the configuration of FIG. 8 illustrated in the first embodiment. More specifically, the layer stack SB has a structure in which the semiconductor layer 31a, the conductive layer 32a, and the conductive layer 32b are stacked in order from a side of the semiconductor substrate 71. The cross-sectional structure other than the layer stack SB is similar to that in FIG. 8 described in the first embodiment.

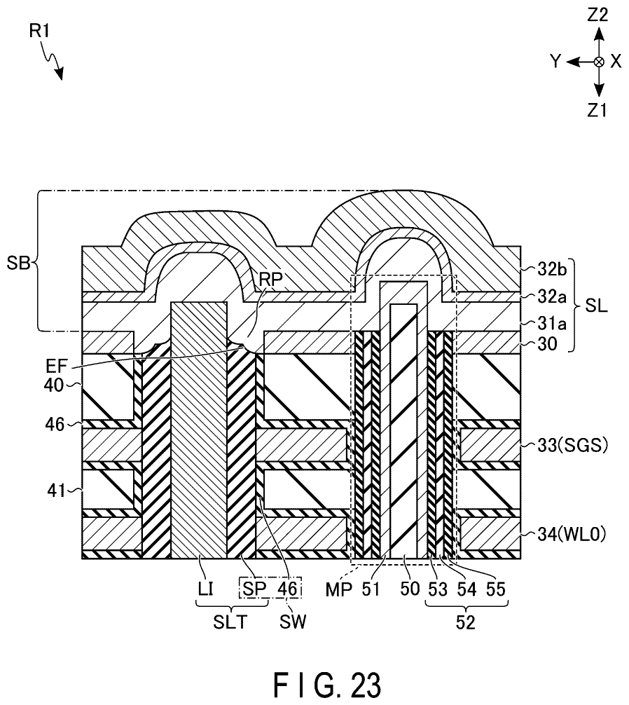

Next, details of cross-sectional structures of the layer stack SB and a vicinity of the layer stack SB will be described. FIG. 23 is an enlarged cross-sectional view of a partial region (region R1) including the layer stack SB of FIG. 22.

As illustrated in FIG. 23, end portions of the spacer SP and the insulator 46 in the Z2 direction are etched. More specifically, the spacer SP and the insulator 46 are etched to a position below an upper surface of the conductor LI in a Z2 direction and an upper surface of the conductive layer 30 in the Z2 direction. That is, end surfaces of the spacer SP and the insulator 46 in the Z2 direction are located below the upper surface of the conductor LI in the Z2 direction and the upper surface of the conductive layer 30 in the Z2 direction. The end surface of the insulator 46 in the Z2 direction reaches the first surface of the conductive layer 30. In other words, the end surface EF of an insulator SW in the Z2 direction is located below the upper surface of the conductor LI in the Z2 direction and the upper surface of the conductive layer 30 in the Z2 direction. A recess portion RP exists between the end surface EF of the insulator SW in the Z2 direction and the conductive layer 30. An angle of the end surface EF of the insulator SW in the Z2 direction with respect to a side surface of the conductive layer 30 is a relatively large angle (an angle close to 90 degrees). A side surface of an end portion of the conductor LI in the Z2 direction and the end surface EF of the insulator SW in the Z2 direction are in contact with the semiconductor layer 31a.

In the Z2 direction, the semiconductor layer 31a is provided on each of the conductive layer 30, the semiconductor film 51, the tunnel insulating film 53, the insulating film 54, the block insulating film 55, the conductor LI, the spacer SP, and the insulator 46. The semiconductor layer 31a includes, for example, doped polysilicon doped with an N-type impurity. The semiconductor layer 31a covers an end portion (an end surface and a side surface of the end portion) of the semiconductor film 51 in the Z2 direction. The semiconductor layer 31a covers an end portion (an end surface and a side surface of the end portion) of the conductor LI in the Z2 direction. The recess portion RP is embedded by the semiconductor layer 31a.

In the Z2 direction, the conductive layer 32a is provided on the semiconductor layer 31a. The conductive layer 32a includes, for example, titanium or titanium nitride. In the Z2 direction, the conductive layer 32b is provided on the conductive layer 32a. The conductive layer 32b includes, for example, tungsten.

### 3.2 Method of Manufacturing Semiconductor Memory Device

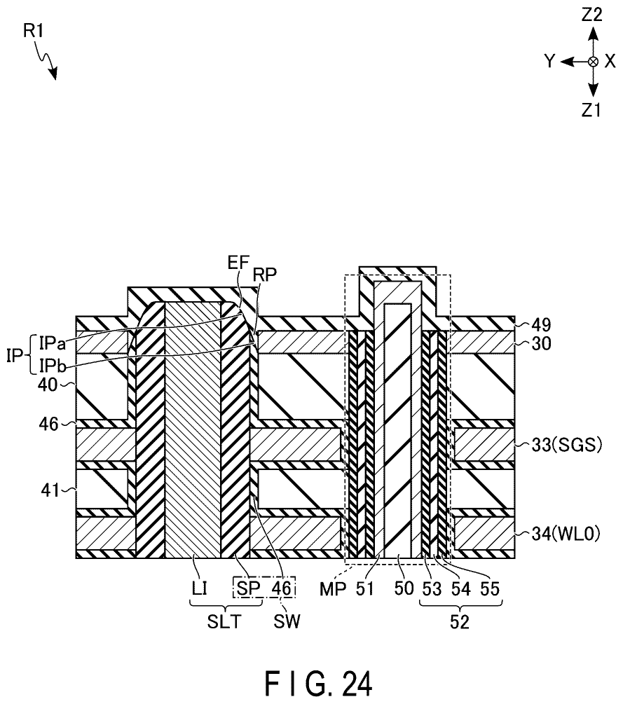

A method of manufacturing the semiconductor memory device 3B will be described with reference to FIGS. 24 to 26. FIGS. 24 to 26 are cross-sectional views for describing an example of a method of manufacturing the semiconductor memory device 3B. FIGS. 24 to 26 illustrate cross-sectional views of a region corresponding to FIG. 23.

First, in a similar manner to the first embodiment, processes up to the process of removing the natural oxide film on the second surface of the conductive layer 30 after removal of the stacked film 52 are performed.

Next, as illustrated in FIG. 24, an insulating layer 49 is formed. For example, the insulating layer 49 is formed by PVD. For example, the insulating layer 49 is formed with a thickness of half or more of a height of the recess portion RP. As the insulating layer 49, for example, silicon oxide is deposited. As a result, in the Z2 direction, the insulating layer 49 is formed on each of the conductive layer 30, the semiconductor film 51, the tunnel insulating film 53, the insulating film 54, the block insulating film 55, the conductor LI, the spacer SP, and the insulator 46.

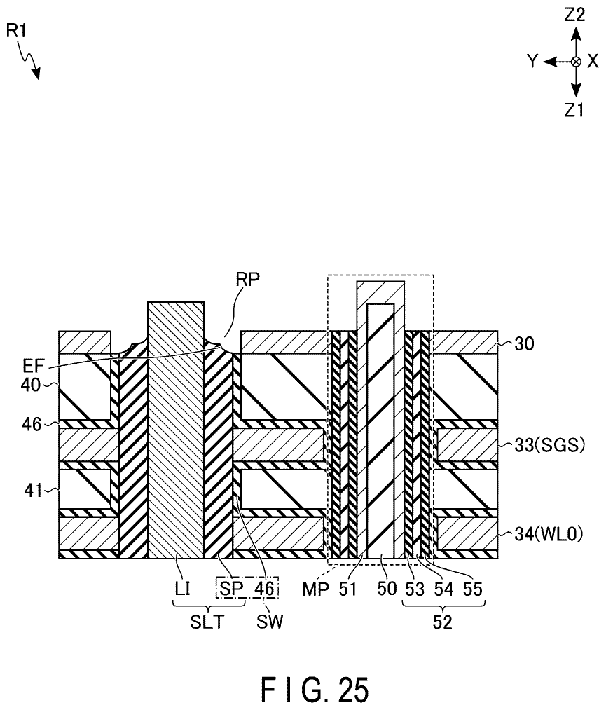

Next, as illustrated in FIG. 25, isotropic etching is performed by wet etching using DHF, for example. An etching rate is relatively high. As a result, the insulating layer 49 is removed, and the end portions of the spacer SP and the insulator 46 in the Z2 direction are etched. Since the etching rate is relatively high, the end portions of the spacer SP and the insulator 46 in the Z2 direction are etched in whole. For example, the end portions of the spacer SP and the insulator 46 in the Z2 direction are cut to positions below the upper surface of the conductor LI in the Z2 direction and the upper surface of the conductive layer 30 in the Z2 direction. The end surface of the insulator 46 in the Z2 direction reaches the first surface of the conductive layer 30. In other words, the position of the end surface EF of the insulator SW in the Z2 direction is located below the upper surface of the conductor LI in the Z2 direction and the upper surface of the conductive layer 30 in the Z2 direction. The recess portion RP is formed between the end surface EF of the insulator SW in the Z2 direction and the conductive layer 30. The angle of the end surface EF of the insulator SW in the Z2 direction with respect to the side surface of the conductive layer 30 is a relatively large angle. In other words, the recess portion RP falls at a relatively large angle.

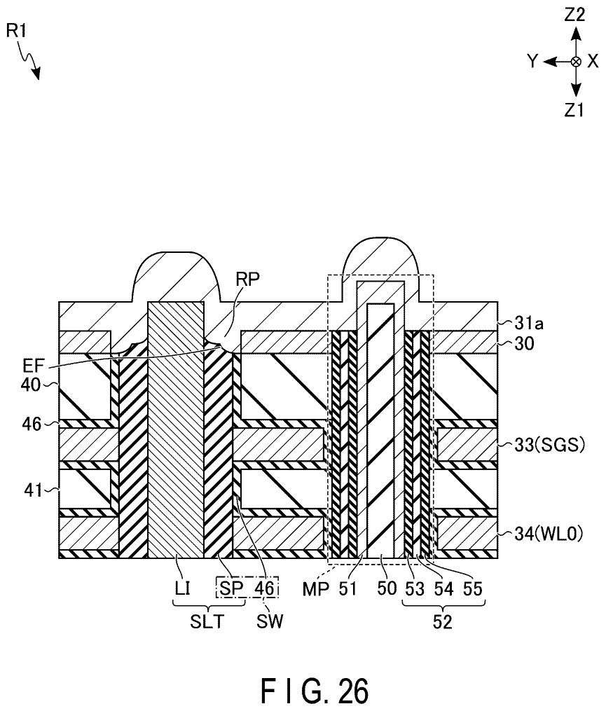

Next, as illustrated in FIG. 26, the semiconductor layer 31a is formed. For example, the semiconductor layer 31a is formed by PVD. For example, amorphous silicon is deposited as the semiconductor layer 31a. As a result, the semiconductor layer 31a is formed on the second surface of each of the conductive layer 30, the plurality of memory pillars MP, and the plurality of members SLT. Specifically, in the Z2 direction, the semiconductor layer 31a is formed on each of the conductive layer 30, the semiconductor film 51, the tunnel insulating film 53, the insulating film 54, the block insulating film 55, the conductor LI, the spacer SP, and the insulator 46. The recess portion RP that falls at a relatively large angle is embedded by the semiconductor layer 31a. Note that the semiconductor layer 31a may be formed by a film forming method other than PVD. For example, the semiconductor layer 31a may be formed by LP-CVD or PE-CVD.

Thereafter, similarly to the first embodiment, processes of introducing impurities, heat treatment, removing the natural oxide film on the second surface of the semiconductor layer 31a, forming the conductive layer 32a, and forming the conductive layer 32b are performed.

### 3.3 Effects According to Present Embodiment

In the present embodiment, after the stacked film 52 of the memory pillar MP and the natural oxide film on the conductive layer 30 are removed, the insulating layer 49 is formed. As a result, the recess portion RP that falls at an acute angle is embedded by the insulating layer 49. Next, etching is performed at a relatively high etching rate. As a result, the insulator SW is etched in whole, and the recess portion RP that falls at a relatively large angle is formed between the insulator SW and the conductive layer 30. Therefore, as compared with a case where the semiconductor layer 31a (amorphous silicon) is formed in the recess portion RP that falls at an acute angle, the coverability for the recess portion RP is improved. Therefore, a recess portion RP is embedded by amorphous silicon. As a result, similarly to the first embodiment, it is possible to suppress dissolution of the insulator SW due to wet etching in the process of removing the natural oxide film before the formation of barrier metal and metal. Therefore, a yield can be improved.

### 3.4 First Modification

A semiconductor memory device according to a first modification of the third embodiment will be described. In a semiconductor memory device 3Ba according to the present modification, a structure of a layer stack SB is different from that of the third embodiment. Hereinafter, differences from the third embodiment will be mainly described.

### 3.4.1 Overall Cross-Sectional Structure of Semiconductor Memory Device

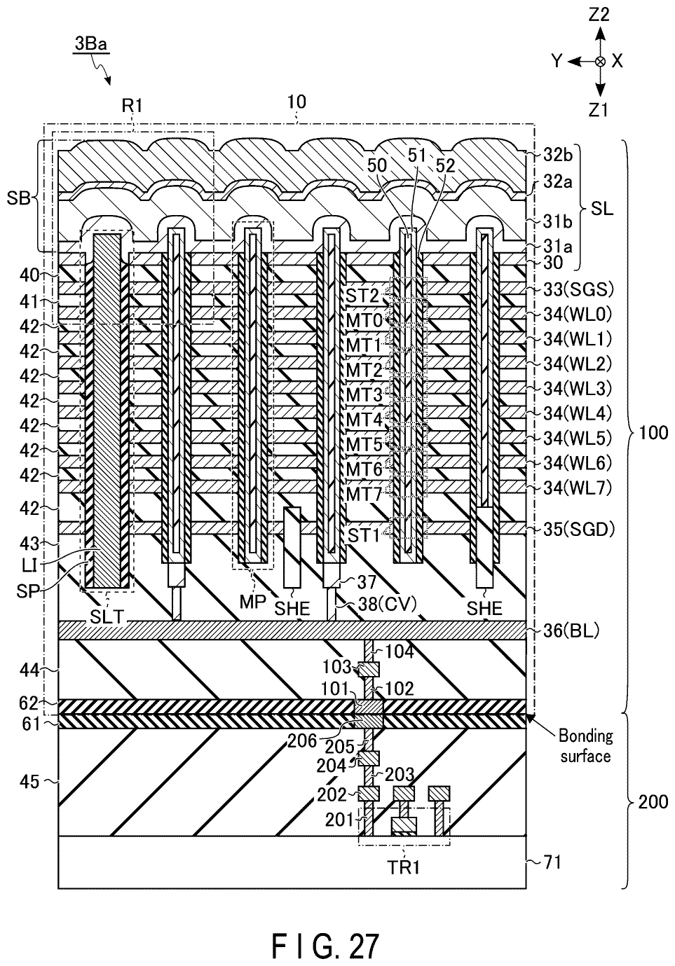

An overall cross-sectional structure of the semiconductor memory device 3Ba will be described with reference to FIG. 27. FIG. 27 is a cross-sectional view illustrating an example of a cross-sectional structure of the semiconductor memory device 3Ba. FIG. 27 illustrates a cross-sectional structure of a part (a region corresponding to the memory region MR of the array chip 100 and the memory region MR of the circuit chip 200) of the semiconductor memory device 3Ba.

As illustrated in FIG. 27, the memory cell array 10 further includes a semiconductor layer 31b in addition to the configuration of FIG. 22 described in the third embodiment. More specifically, the layer stack SB has a structure in which the semiconductor layer 31b is further provided between the semiconductor layer 31a and the conductive layer 32a. The cross-sectional structure other than the layer stack SB is similar to that in FIG. 22 described in the third embodiment.

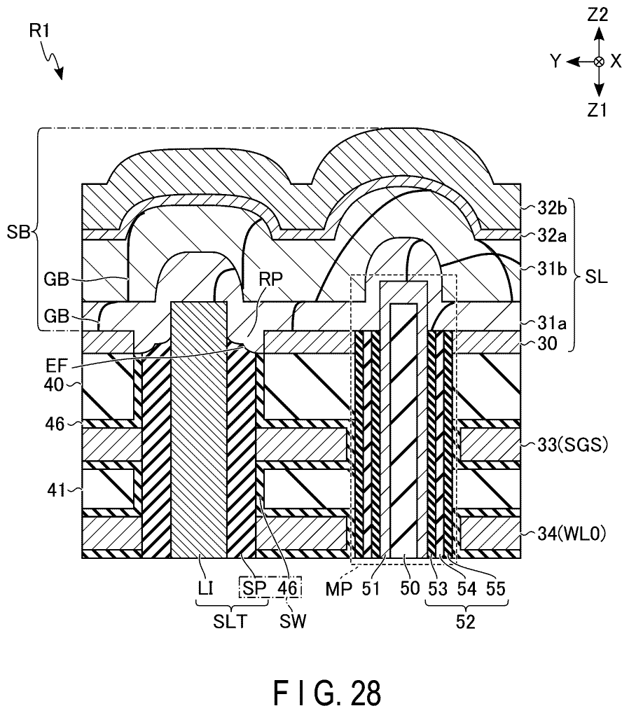

Next, details of cross-sectional structures of the layer stack SB and a vicinity of the layer stack SB will be described. FIG. 28 is an enlarged cross-sectional view of a partial region (region R1) including the layer stack SB of FIG. 27.

As illustrated in FIG. 28, the semiconductor layer 31b is provided on the semiconductor layer 31a in the Z2 direction. The semiconductor layer 31b includes, for example, doped polysilicon doped with an N-type impurity. In the Z2 direction, the conductive layer 32a is provided on the semiconductor layer 31b.

### 3.4.2 Method of Manufacturing Semiconductor Memory Device

In a method of manufacturing the semiconductor memory device 3Ba, for example, the process of forming the semiconductor layer 31b described in the first embodiment is inserted between the process of forming the semiconductor layer 31a and the process of forming the conductive layer 32a in the manufacturing method described in the third embodiment.

### 3.4.3 Effects According to Present Modification

According to the present modification, effects similar to those of the third embodiment are obtained. Further, effects similar to those of the first embodiment are obtained.

### 3.5 Second Modification

A semiconductor memory device according to a second modification of the third embodiment will be described. In a semiconductor memory device 3Bb according to the present modification, a structure of a layer stack SB is different from that of the first modification of the third embodiment. Hereinafter, differences from the first modification of the third embodiment will be mainly described.

### 3.5.1 Overall Cross-Sectional Structure of Semiconductor Memory Device

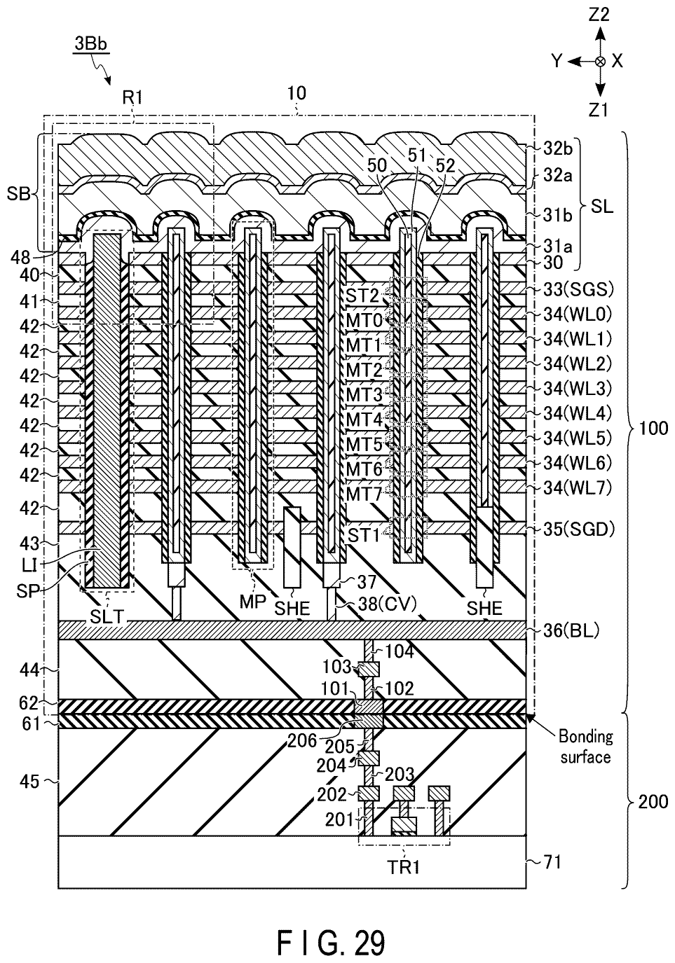

An overall cross-sectional structure of the semiconductor memory device 3Bb will be described with reference to FIG. 29. FIG. 29 is a cross-sectional view illustrating an example of a cross-sectional structure of the semiconductor memory device 3Bb. FIG. 29 illustrates a cross-sectional structure of a part (a region corresponding to the memory region MR of the array chip 100 and the memory region MR of the circuit chip 200) of the semiconductor memory device 3Bb.

As illustrated in FIG. 29, the memory cell array 10 further includes an insulating layer 48 in addition to the configuration of FIG. 27 described in the first modification of the third embodiment. More specifically, the layer stack SB has a structure in which the insulating layer 48 is further provided between the semiconductor layer 31a and the semiconductor layer 31b. The cross-sectional structure other than the layer stack SB is similar to that in FIG. 27 described in the first modification of the third embodiment.

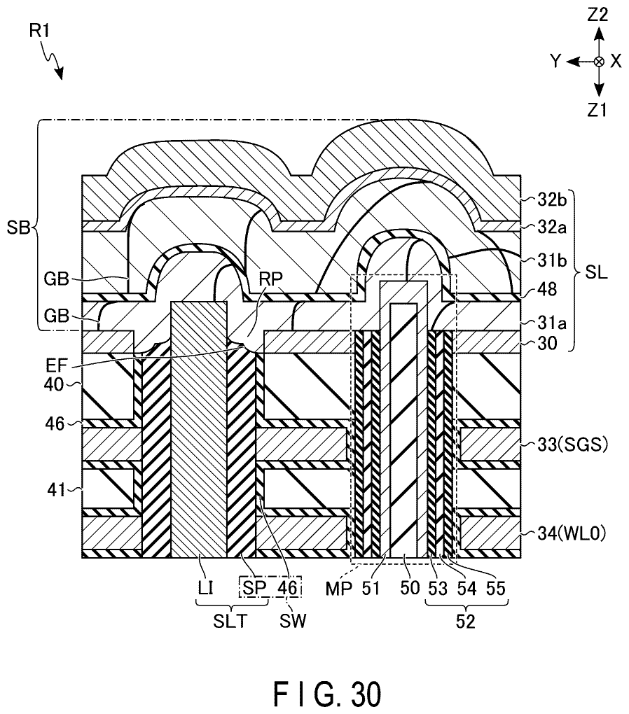

Next, details of cross-sectional structures of the layer stack SB and a vicinity of the layer stack SB will be described. FIG. 30 is an enlarged cross-sectional view of a partial region (region R1) including the layer stack SB of FIG. 29.

As illustrated in FIG. 30, the insulating layer 48 is provided on the semiconductor layer 31b in the Z2 direction. The insulating layer 48 includes, for example, silicon oxide or silicon nitride. In the Z2 direction, the conductive layer 32a is provided on the insulating layer 48.

### 3.5.2 Method of Manufacturing Semiconductor Memory Device

In a method of manufacturing the semiconductor memory device 3Bb, for example, the process of forming the insulating layer 48 described in the second embodiment is inserted between the process of forming the semiconductor layer 31a and the process of forming the semiconductor layer 31b in the manufacturing method described in the first modification of the third embodiment.

### 3.5.3 Effects According to Present Modification

According to the present modification, effects similar to those of the third embodiment are obtained. Further, effects similar to those of the second embodiment are obtained.

### 4. Fourth Embodiment

A semiconductor memory device according to a fourth embodiment will be described. In a semiconductor memory device 3C according to the present embodiment, a structure of a layer stack SB is different from that of the first embodiment. Hereinafter, differences from the first embodiment will be mainly described.

### 4.1 Overall Cross-Sectional Structure of Semiconductor Memory Device

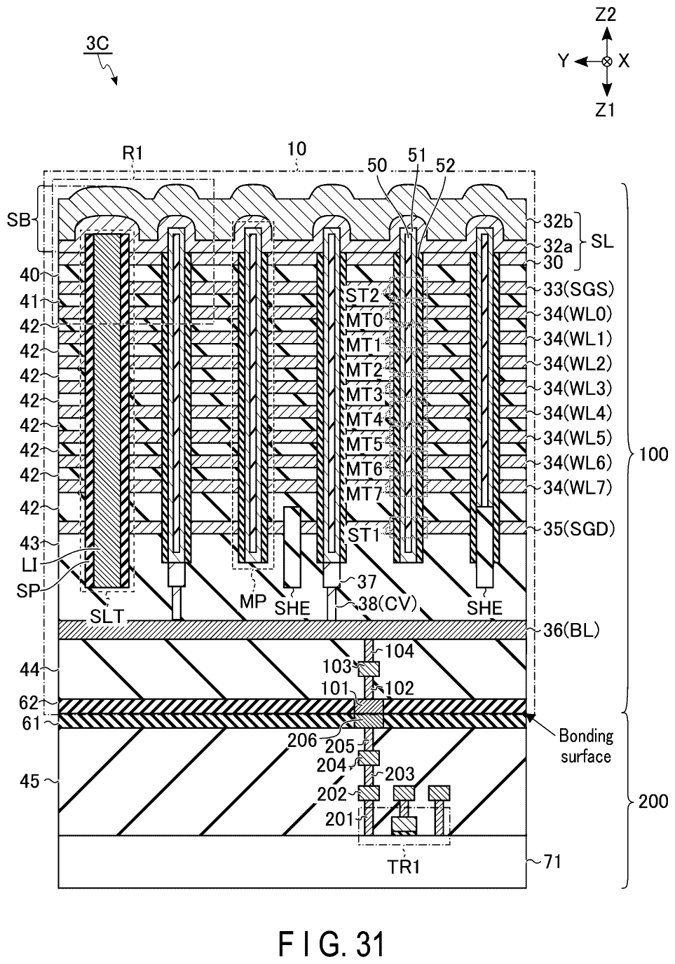

An overall cross-sectional structure of the semiconductor memory device 3C will be described with reference to FIG. 31. FIG. 31 is a cross-sectional view illustrating an example of a cross-sectional structure of the semiconductor memory device 3C. FIG. 31 illustrates a cross-sectional structure of a part (a region corresponding to the memory region MR of the array chip 100 and the memory region MR of the circuit chip 200) of the semiconductor memory device 3C.

As illustrated in FIG. 31, in the memory cell array 10, the semiconductor layers 31a and 31b are eliminated from the configuration of FIG. 8 illustrated in the first embodiment. The layer stack SB has a structure in which the conductive layers 32a and 32b are stacked in order from a side of the semiconductor substrate 71. The cross-sectional structure other than the layer stack SB is similar to that in FIG. 8 described in the first embodiment.

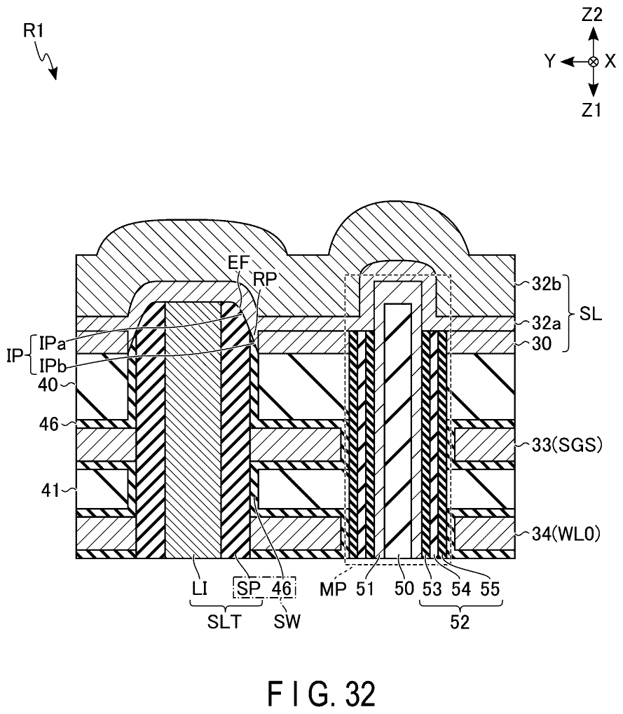

Next, details of cross-sectional structures of the layer stack SB and a vicinity of the layer stack SB will be described. FIG. 32 is an enlarged cross-sectional view of a partial region (region R1) including the layer stack SB of FIG. 31.

As illustrated in FIG. 32, end portions of the spacer SP and the insulator 46 in the Z2 direction are etched. More specifically, a corner on a side not in contact with the conductor LI of the end portion of the spacer SP in the Z2 direction is etched. That is, the end surface of the spacer SP in the Z2 direction has the inclined portion IPa on the side not in contact with the conductor LI. The end portion of the insulator 46 in the Z2 direction is etched to the first surface of the conductive layer 30. That is, the end surface of the insulator 46 in the Z2 direction has the inclined portion IPb along the inclined portion IPa. The inclined portion IPb reaches the first surface of the conductive layer 30. In other words, the end surface EF of an insulator SW in the Z2 direction has the inclined portion IP on the side not in contact with the conductor LI. The inclined portion IP includes the inclined portion IPa and the inclined portion IPb. A recess portion RP exists between the inclined portion IP and the conductive layer 30. An angle of the inclined portion IP with respect to the side surface of the conductive layer 30 is an acute angle. The inclined portion IP is in contact with the conductive layer 32a. Further, the inclined portion IP is in contact with the conductive layer 30 at a position below an upper surface of the conductive layer 30 in the Z2 direction.

In the Z2 direction, the conductive layer 32a is provided on each of the conductive layer 30, the semiconductor film 51, the tunnel insulating film 53, the insulating film 54, the block insulating film 55, the conductor LI, the spacer SP, and the insulator 46. The conductive layer 32a includes, for example, titanium or titanium nitride. The conductive layer 32a covers an end portion (an end surface and a side surface of the end portion) of the semiconductor film 51 in the Z2 direction. The conductive layer 32a covers an end portion of the member SLT in the Z2 direction (an end surface of the conductor LI in the Z2 direction, an end surface of the spacer SP in the Z2 direction, and an end surface of the insulator 46 in the Z2 direction). The recess portion RP is embedded by the conductive layer 32a. In the Z2 direction, the conductive layer 32b is provided on the conductive layer 32a. The conductive layer 32b includes, for example, tungsten.

### 4.2 Method of Manufacturing Semiconductor Memory Device

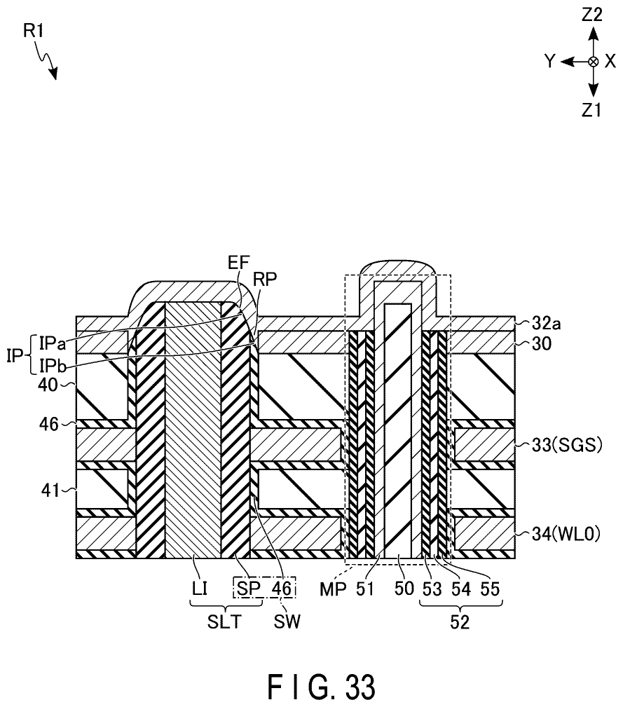

A method of manufacturing the semiconductor memory device 3C will be described with reference to FIG. 33. FIG. 33 is a cross-sectional view for describing an example of a method of manufacturing the semiconductor memory device 3C. FIG. 33 illustrates a cross-sectional view of a region corresponding to FIG. 32.

First, in a similar manner to the first embodiment, processes up to a process of removing the natural oxide film on the second surface of the conductive layer 30 after removal of the stacked film 52 are performed.

Next, as illustrated in FIG. 33, the conductive layer 32a is formed. For example, the conductive layer 32a is formed by PVD. As the conductive layer 32a, for example, titanium or titanium nitride is deposited. As a result, in the Z2 direction, the conductive layer 32a is formed on each of the conductive layer 30, the semiconductor film 51, the tunnel insulating film 53, the insulating film 54, the block insulating film 55, the conductor LI, the spacer SP, and the insulator 46. As a material having a relatively high coverability is formed as the conductive layer 32a, the recess portion RP that falls at an acute angle is also embedded by the conductive layer 32a. Note that the conductive layer 32a may be formed by a film forming method other than PVD. For example, the conductive layer 32a may be formed by LP-CVD or PE-CVD.

Next, the conductive layer 32b is formed. For example, the conductive layer 32b is formed by PVD. As the conductive layer 32b, for example, tungsten is deposited. As a result, the conductive layer 32b is formed on the conductive layer 32a in the Z2 direction, and the structure illustrated in FIG. 32 is formed. Note that the conductive layer 32b may be formed by a film forming method other than PVD. For example, the conductive layer 32b may be formed by LP-CVD or PE-CVD.

### 4.3 Effects According to Present Embodiment

In the present embodiment, the two conductive layers are formed as the layer stack SB covering the semiconductor film 51 and the member SLT. For example, the conductive layers 32a and 32b are formed. As the conductive layer 32a, for example, titanium or titanium nitride is deposited. Since these materials have a relatively high coverability, the coverability for the recess portion RP that falls at an acute angle is improved as compared with a case where a material having a relatively low coverability is formed. Therefore, the recess portion RP is embedded by the conductive layer 32a. As a result, similarly to the first embodiment, it is possible to suppress dissolution of the insulator SW due to wet etching in the process of removing the natural oxide film before the formation of barrier metal and metal. Therefore, a yield can be improved.

In the present embodiment, since a semiconductor layer is not included in the layer stack SB, it is not necessary to consider movement of grains of the semiconductor layer (amorphous silicon) due to heat treatment.

### 5. Fifth Embodiment

A semiconductor memory device according to a fifth embodiment will be described. In a semiconductor memory device 3D according to the present embodiment, structures of a layer stack SB and an insulator SW are different from those of the first embodiment. Hereinafter, differences from the first embodiment will be mainly described.

### 5.1 Overall Cross-Sectional Structure of Semiconductor Memory Device

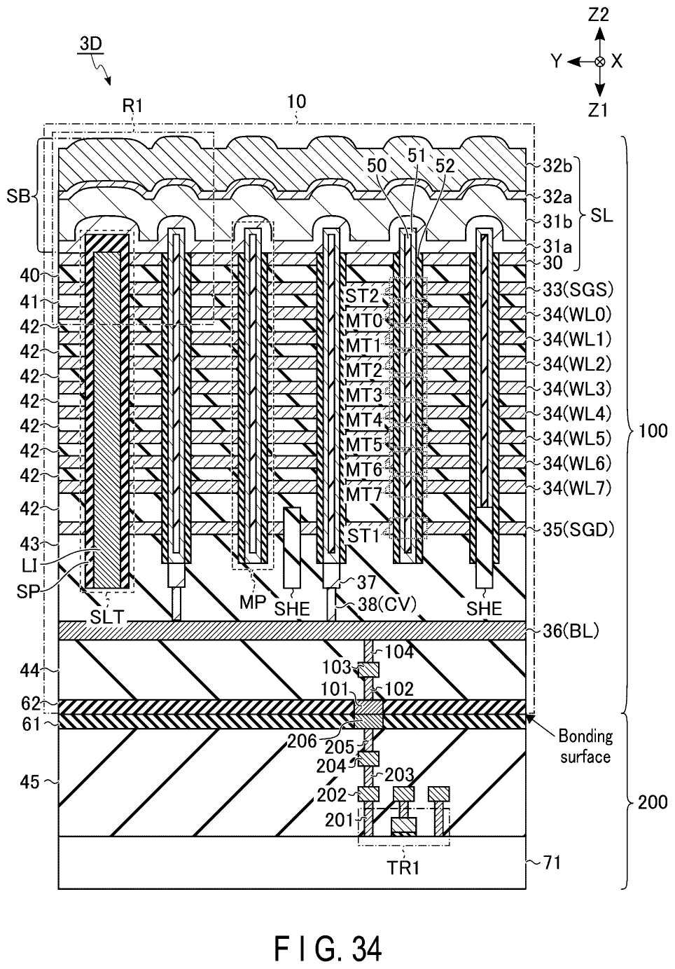

An overall cross-sectional structure of the semiconductor memory device 3D will be described with reference to FIG. 34. FIG. 34 is a cross-sectional view illustrating an example of a cross-sectional structure of the semiconductor memory device 3D. FIG. 34 illustrates a cross-sectional structure of a part (a region corresponding to the memory region MR of the array chip 100 and the memory region MR of the circuit chip 200) of the semiconductor memory device 3D.

As illustrated in FIG. 34, in the layer stack SB, an end surface of the conductor LI in the Z2 direction is covered with the spacer SP. That is, in the Z2 direction, the end surface of the conductor LI is not in contact with the semiconductor layer 31a. In the Z2 direction, an end surface of the spacer SP is in contact with the semiconductor layer 31a. The cross-sectional structure other than the layer stack SB and the insulator SW to be described later is similar to that in FIG. 8 described in the first embodiment.

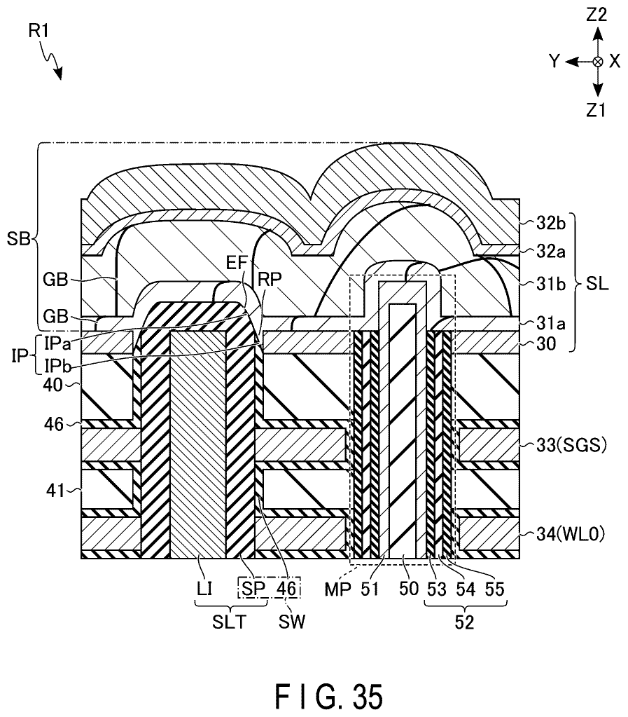

Next, details of cross-sectional structures of the layer stack SB and a vicinity of the layer stack SB will be described. FIG. 35 is an enlarged cross-sectional view of a partial region (region R1) including the layer stack SB of FIG. 34.

As illustrated in FIG. 35, the cross-sectional structure of each of the layer stack SB and the insulator SW is similar to that in FIG. 9 described in the first embodiment except that the end surface of the conductor LI in the Z2 direction is covered with the spacer SP. That is, the cross-sectional structure of each of the semiconductor layer 31a, the semiconductor layer 31b, the conductive layer 32a, the conductive layer 32b, and the insulator 46 is similar to that in FIG. 9 described in the first embodiment.

### 5.2 Method of Manufacturing Semiconductor Memory Device

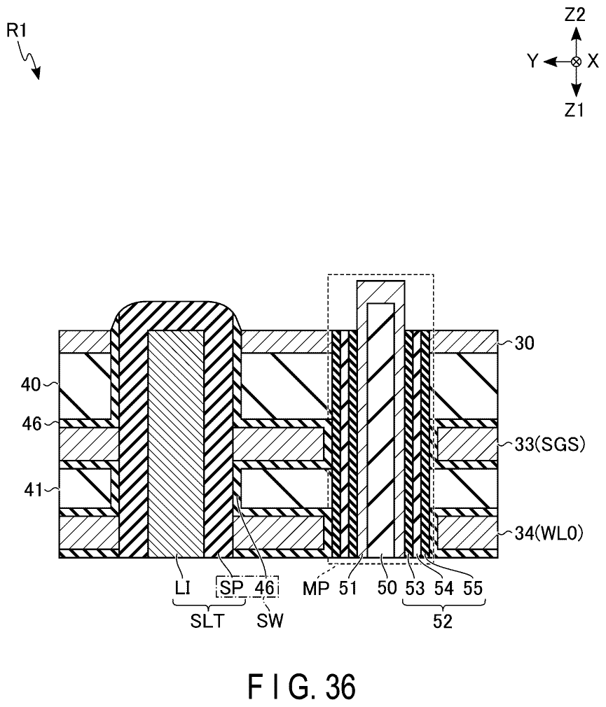

A method of manufacturing the semiconductor memory device 3D will be described with reference to FIG. 36. FIG. 36 is a cross-sectional view for describing an example of a method of manufacturing the semiconductor memory device 3D. FIG. 36 illustrates a cross-sectional view of a region corresponding to FIG. 35.

Processes up to a process of removing the stacked film 52 are performed similar to the first embodiment, except that not only a side surface of the conductor LI but also a bottom surface of the conductor LI is covered with the spacer SP in formation of the member SLT. As a result, the structure illustrated in FIG. 36 is formed.

Thereafter, processes of removal of the natural oxide film on the second surface of the conductive layer 30, formation of the semiconductor layer 31a, formation of the semiconductor layer 31b, introduction of impurities, heat treatment, removal of the natural oxide film on the second surface of the semiconductor layer 31b, formation of the conductive layer 32a, and formation of the conductive layer 32b are performed in a similar manner to the first embodiment. As a result, the structure illustrated in FIG. 35 is formed.

### 5.3 Effects According to Present Embodiment

According to the present embodiment, effects similar to those of the first embodiment are obtained.

### 6. Sixth Embodiment

A semiconductor memory device according to a sixth embodiment will be described. In a semiconductor memory device 3E according to the present embodiment, structures of a layer stack SB and an insulator SW are different from those of the second embodiment. Hereinafter, differences from the second embodiment will be mainly described.

### 6.1 Overall Cross-Sectional Structure of Semiconductor Memory Device

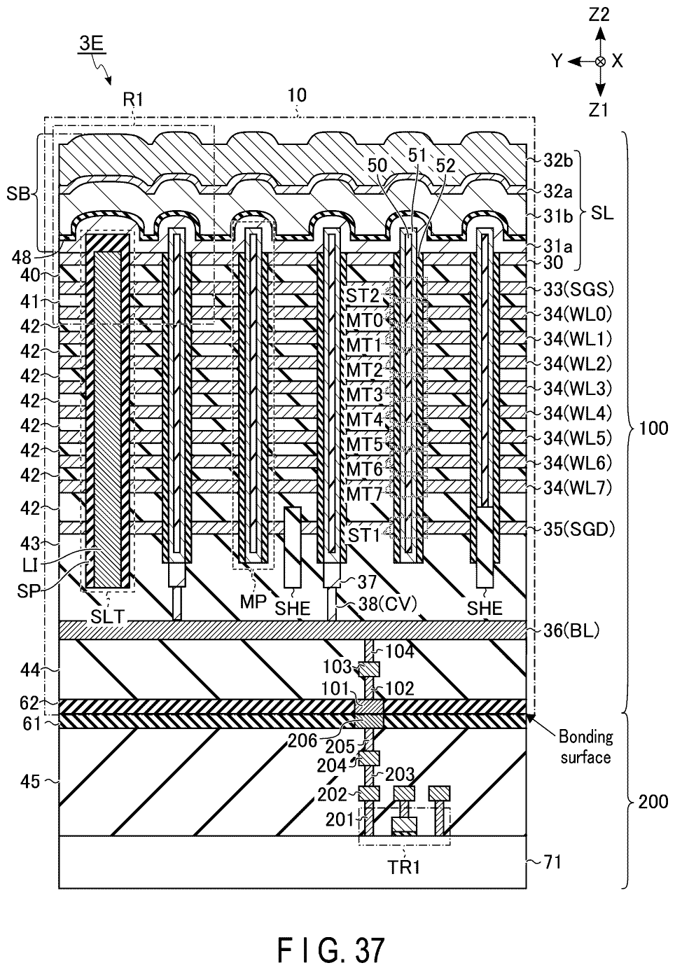

An overall cross-sectional structure of the semiconductor memory device 3E will be described with reference to FIG. 37. FIG. 37 is a cross-sectional view illustrating an example of a cross-sectional structure of the semiconductor memory device 3E. FIG. 37 illustrates a cross-sectional structure of a part (a region corresponding to the memory region MR of the array chip 100 and the memory region MR of the circuit chip 200) of the semiconductor memory device 3E.

As illustrated in FIG. 37, in the layer stack SB, an end surface of the conductor LI in a Z2 direction is covered with the spacer SP, similarly to the fifth embodiment. The cross-sectional structure other than the layer stack SB and the insulator SW to be described later is similar to that in FIG. 18 described in the second embodiment.

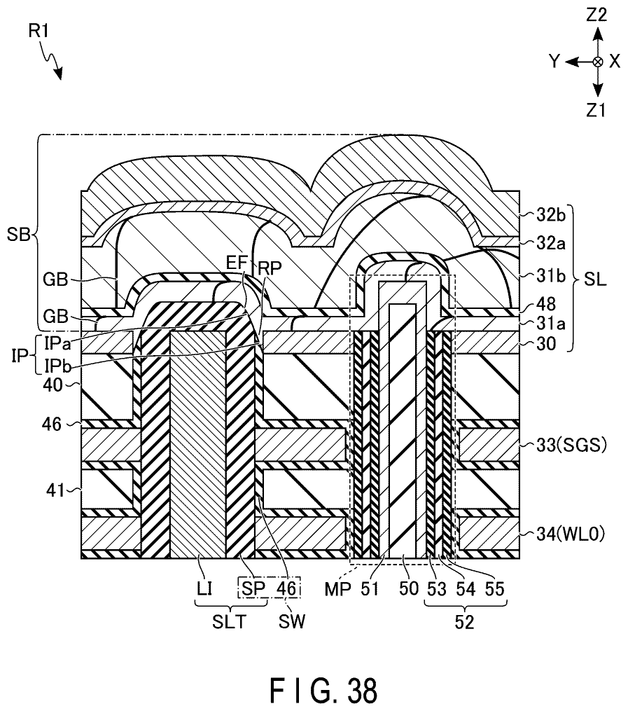

Next, details of cross-sectional structures of the layer stack SB and a vicinity of the layer stack SB will be described. FIG. 38 is an enlarged cross-sectional view of a partial region (region R1) including the layer stack SB of FIG. 37.

As illustrated in FIG. 38, the cross-sectional structure of each of the layer stack SB and the insulator SW is similar to that in FIG. 19 described in the second embodiment except that the end surface of the conductor LI in the Z2 direction is covered with the spacer SP. That is, the cross-sectional structure of each of the semiconductor layer 31a, the insulating layer 48, the semiconductor layer 31b, the conductive layer 32a, the conductive layer 32b, and the insulator 46 is similar to that in FIG. 19 described in the second embodiment.

### 6.2 Method of Manufacturing Semiconductor Memory Device

A method of manufacturing the semiconductor memory device 3E will be described.

First, in a similar manner to the fifth embodiment, the member SLT is formed and processes up to a process of removing the natural oxide film on the second surface of the conductive layer 30 after removal of the stacked film 52 are performed. As a result, the structure illustrated in FIG. 36 is formed, similarly to the fifth embodiment.

Thereafter, processes of removal of the natural oxide film on the second surface of the conductive layer 30, formation of the semiconductor layer 31a, heat treatment, formation of the insulating layer 48, formation of the semiconductor layer 31b, introduction of impurities, heat treatment, removal of the natural oxide film on the second surface of the semiconductor layer 31b, formation of the conductive layer 32a, and formation of the conductive layer 32b are performed in a similar manner to the second embodiment. As a result, the structure illustrated in FIG. 38 is formed.

### 6.3 Effects According to Present Embodiment

According to the present embodiment, effects similar to those of the second embodiment are obtained.

### 7. Seventh Embodiment

A semiconductor memory device according to a seventh embodiment will be described. In a semiconductor memory device 3F according to the present embodiment, a structure of a layer stack SB is different from that of the third embodiment. Hereinafter, differences from the third embodiment will be mainly described.

### 7.1 Overall Cross-Sectional Structure of Semiconductor Memory Device

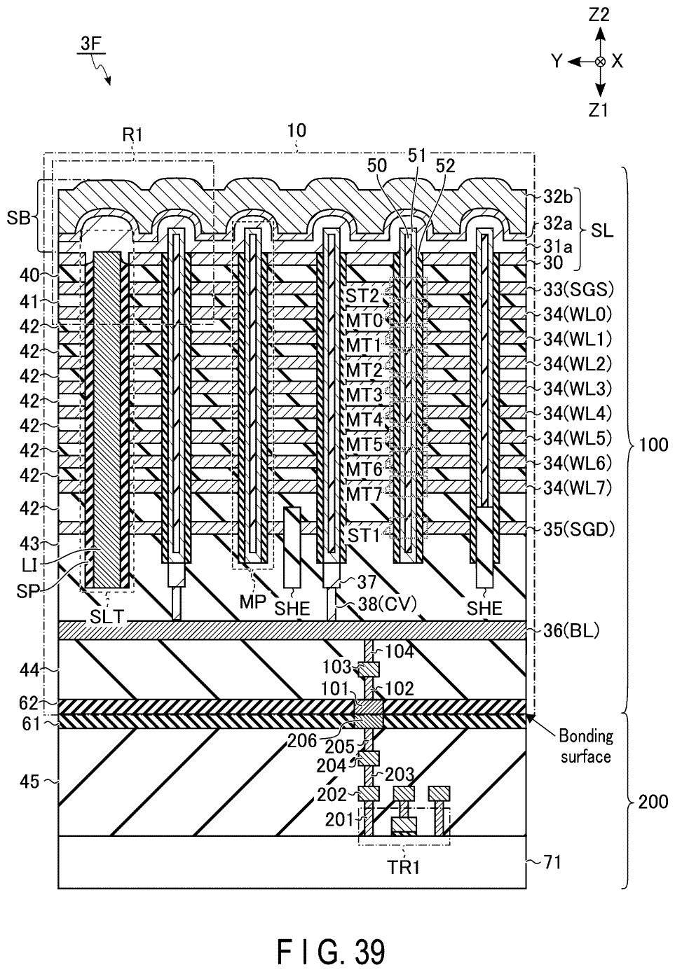

An overall cross-sectional structure of the semiconductor memory device 3F will be described with reference to FIG. 39. FIG. 39 is a cross-sectional view illustrating an example of a cross-sectional structure of the semiconductor memory device 3F. FIG. 39 illustrates a cross-sectional structure of a part (a region corresponding to the memory region MR of the array chip 100 and the memory region MR of the circuit chip 200) of the semiconductor memory device 3F.

As illustrated in FIG. 39, in the layer stack SB, since an end surface of the conductor LI in the Z2 direction is covered with the spacer SP in a process of forming the member SLT to be described later, the end surface of the conductor LI in the Z2 direction is located below end surfaces of the core member 50 and the semiconductor film 51 in the Z2 direction. The cross-sectional structure other than the layer stack SB is similar to that in FIG. 22 described in the third embodiment.

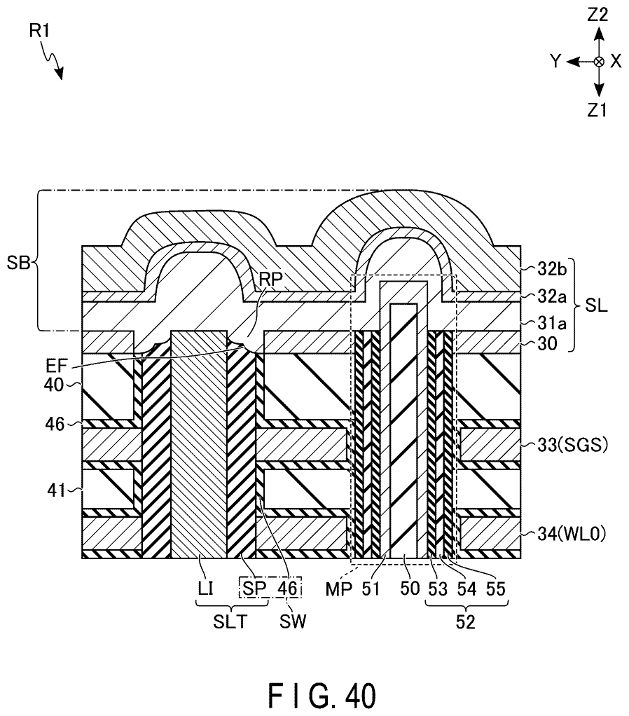

Next, details of cross-sectional structures of the layer stack SB and a vicinity of the layer stack SB will be described. FIG. 40 is an enlarged cross-sectional view of a partial region (region R1) including the layer stack SB of FIG. 39.

As illustrated in FIG. 40, the cross-sectional structure of the layer stack SB is similar to that in FIG. 23 illustrated in the third embodiment except that the end surface of the conductor LI is located below the end surfaces of the core member 50 and the semiconductor film 51 in the Z2 direction. That is, the cross-sectional structure of each of the semiconductor layer 31a, the conductive layer 32a, and the conductive layer 32b is similar to that in FIG. 23 described in the third embodiment.

### 7.2 Method of Manufacturing Semiconductor Memory Device

A method of manufacturing the semiconductor memory device 3F will be described.

First, in a similar manner to the fifth embodiment, the member SLT is formed and processes up to a process of removing the natural oxide film on the second surface of the conductive layer 30 after removal of the stacked film 52 are performed. As a result, the structure illustrated in FIG. 36 is formed, similarly to the fifth embodiment.

Thereafter, processes of removal of the natural oxide film on the second surface of the conductive layer 30, formation of the insulating layer 49, removal of the insulating layer 49, formation of the semiconductor layer 31a, introduction of impurities, heat treatment, removal of the natural oxide film on the second surface of the semiconductor layer 31a, formation of the conductive layer 32a, and formation of the conductive layer 32b are performed in a similar manner to the third embodiment. As a result, the structure illustrated in FIG. 40 is formed.

### 7.3 Effects According to Present Embodiment

According to the present embodiment, effects similar to those of the third embodiment are obtained.

### 7.4 First Modification

A semiconductor memory device according to a first modification of the seventh embodiment will be described. In a semiconductor memory device 3Fa according to the present modification, a structure of a layer stack SB is different from that of the first modification of the third embodiment. Hereinafter, differences from the first modification of the third embodiment will be mainly described.

### 7.4.1 Overall Cross-Sectional Structure of Semiconductor Memory Device

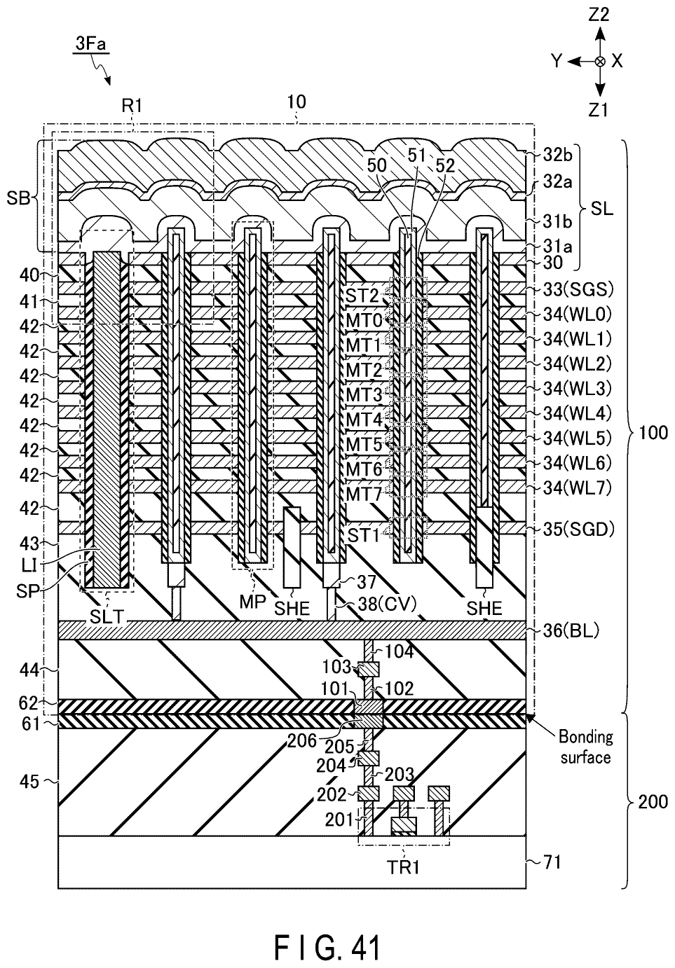

An overall cross-sectional structure of the semiconductor memory device 3Fa will be described with reference to FIG. 41. FIG. 41 is a cross-sectional view illustrating an example of a cross-sectional structure of the semiconductor memory device 3Fa. FIG. 41 illustrates a cross-sectional structure of a part (a region corresponding to the memory region MR of the array chip 100 and the memory region MR of the circuit chip 200) of the semiconductor memory device 3Fa.

As illustrated in FIG. 41, in the layer stack SB, the end surface of the conductor LI in the Z2 direction is located below the end surfaces of the core member 50 and the semiconductor film 51 in the Z2 direction. The cross-sectional structure other than the layer stack SB is similar to that in FIG. 27 described in the first modification of the third embodiment.

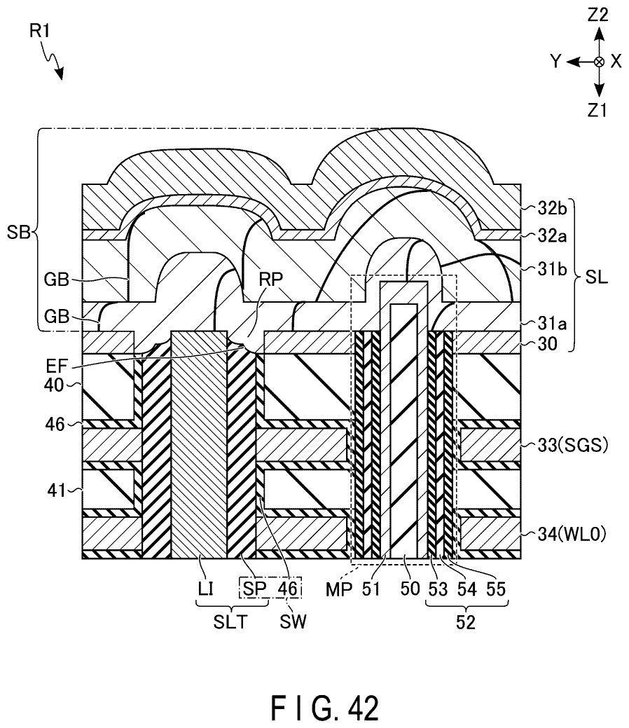

Next, details of cross-sectional structures of the layer stack SB and a vicinity of the layer stack SB will be described. FIG. 42 is an enlarged cross-sectional view of a partial region (region R1) including the layer stack SB of FIG. 41.

As illustrated in FIG. 42, the cross-sectional structure of the layer stack SB is similar to that in FIG. 28 illustrated in the first modification of the third embodiment except that the end surface of the conductor LI is located below the end surfaces of the core member 50 and the semiconductor film 51 in the Z2 direction. That is, the cross-sectional structure of each of the semiconductor layer 31a, the semiconductor layer 31b, the conductive layer 32a, and the conductive layer 32b is similar to that in FIG. 28 described in the first modification of the third embodiment.

### 7.4.2 Method of Manufacturing Semiconductor Memory Device

A method of manufacturing the semiconductor memory device 3Fa will be described.

First, in a similar manner to the fifth embodiment, the member SLT is formed and processes up to a process of removing the natural oxide film on the second surface of the conductive layer 30 after removal of the stacked film 52 are performed. As a result, the structure illustrated in FIG. 36 is formed, similarly to the fifth embodiment.

Thereafter, processes of removal of the natural oxide film on the second surface of the conductive layer 30, formation of the insulating layer 49, removal of the insulating layer 49, formation of the semiconductor layer 31a, formation of the semiconductor layer 31b, introduction of impurities, heat treatment, removal of the natural oxide film on the second surface of the semiconductor layer 31a, formation of the conductive layer 32a, and formation of the conductive layer 32b are performed in a similar manner to the first modification of the third embodiment. As a result, the structure illustrated in FIG. 42 is formed.

### 7.4.3 Effects According to Present Modification

According to the present modification, effects similar to those of the first modification of the third embodiment are obtained.

### 7.5 Second Modification

A semiconductor memory device according to a second modification of the seventh embodiment will be described. In a semiconductor memory device 3Fb according to the present modification, a structure of a layer stack SB is different from that of the second modification of the third embodiment. Hereinafter, differences from the second modification of the third embodiment will be mainly described.

### 7.5.1 Overall Cross-Sectional Structure of Semiconductor Memory Device

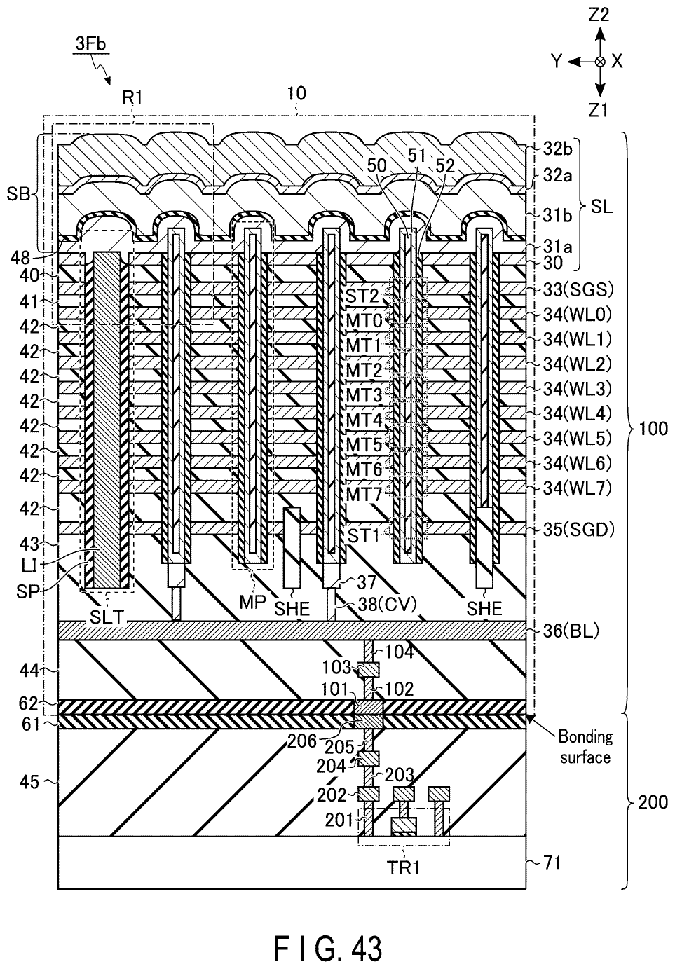

An overall cross-sectional structure of the semiconductor memory device 3Fb will be described with reference to FIG. 43. FIG. 43 is a cross-sectional view illustrating an example of a cross-sectional structure of the semiconductor memory device 3Fb. FIG. 43 illustrates a cross-sectional structure of a part (a region corresponding to the memory region MR of the array chip 100 and the memory region MR of the circuit chip 200) of the semiconductor memory device 3Fb.

As illustrated in FIG. 43, in the layer stack SB, the end surface of the conductor LI in the Z2 direction is located below the end surfaces of the core member 50 and the semiconductor film 51 in the Z2 direction. The cross-sectional structure other than the layer stack SB is similar to that in FIG. 29 described in the second modification of the third embodiment.

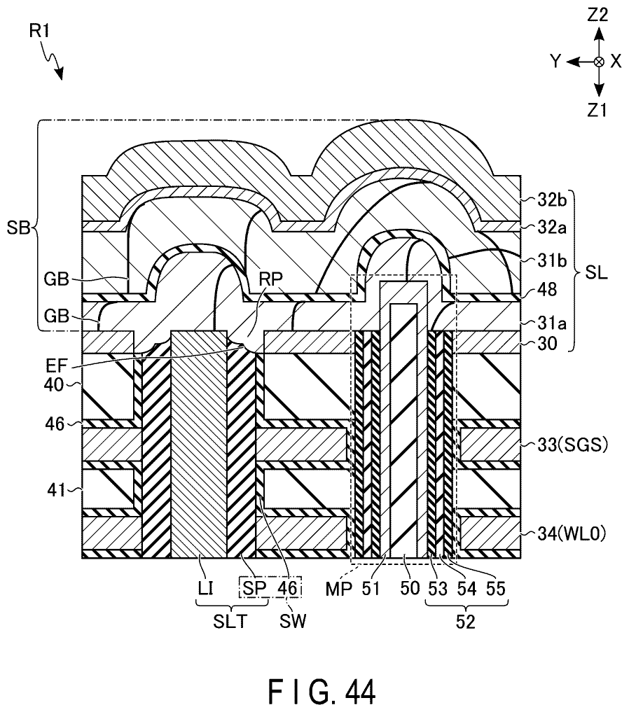

Next, details of cross-sectional structures of the layer stack SB and a vicinity of the layer stack SB will be described. FIG. 44 is an enlarged cross-sectional view of a partial region (region R1) including the layer stack SB of FIG. 43.

As illustrated in FIG. 44, the cross-sectional structure of the layer stack SB is similar to that in FIG. 30 illustrated in the second modification of the third embodiment except that the end surface of the conductor LI is located below the end surfaces of the core member 50 and the semiconductor film 51 in the Z2 direction. That is, the cross-sectional structure of each of the semiconductor layer 31a, the insulating layer 48, the semiconductor layer 31b, the conductive layer 32a, and the conductive layer 32b is similar to that in FIG. 30 described in the second modification of the third embodiment.

### 7.5.2 Method of Manufacturing Semiconductor Memory Device

A method of manufacturing the semiconductor memory device 3Fb will be described.

First, in a similar manner to the fifth embodiment, the member SLT is formed and processes up to a process of removing the natural oxide film on the second surface of the conductive layer 30 after removal of the stacked film 52 are performed. As a result, the structure illustrated in FIG. 36 is formed, similarly to the fifth embodiment. Thereafter, processes of removal of the natural oxide film on the second surface of the conductive layer 30, formation of the insulating layer 49, removal of the insulating layer 49, formation of the semiconductor layer 31a, heat treatment, formation of the insulating layer 48, formation of the semiconductor layer 31b, introduction of impurities, heat treatment, removal of the natural oxide film on the second surface of the semiconductor layer 31a, formation of the conductive layer 32a, and formation of the conductive layer 32b are performed in a similar manner to the second modification of the third embodiment. As a result, the structure illustrated in FIG. 44 is formed.

### 7.5.3 Effects According to Present Modification

According to the present modification, effects similar to those of the second modification of the third embodiment are obtained.

### 8. Eighth Embodiment

A semiconductor memory device according to an eighth embodiment will be described. In a semiconductor memory device 3G according to the present embodiment, structures of a layer stack SB and an insulator SW are different from those of the fourth embodiment. Hereinafter, differences from the fourth embodiment will be mainly described.

### 8.1 Overall Cross-Sectional Structure of Semiconductor Memory Device

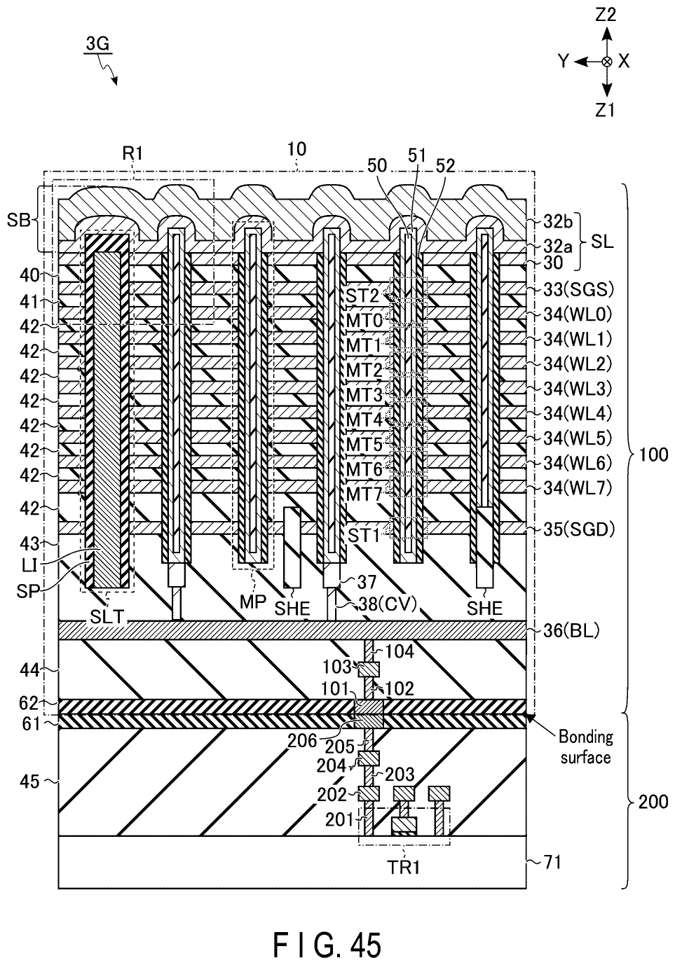

An overall cross-sectional structure of the semiconductor memory device 3G will be described with reference to FIG. 45. FIG. 45 is a cross-sectional view illustrating an example of a cross-sectional structure of the semiconductor memory device 3G. FIG. 45 illustrates a cross-sectional structure of a part (a region corresponding to the memory region MR of the array chip 100 and the memory region MR of the circuit chip 200) of the semiconductor memory device 3G.

As illustrated in FIG. 45, in the layer stack SB, an end surface of the conductor LI in the Z2 direction is covered with the spacer SP. The cross-sectional structure other than the layer stack SB and the insulator SW to be described later is similar to that in FIG. 31 described in the fourth embodiment.

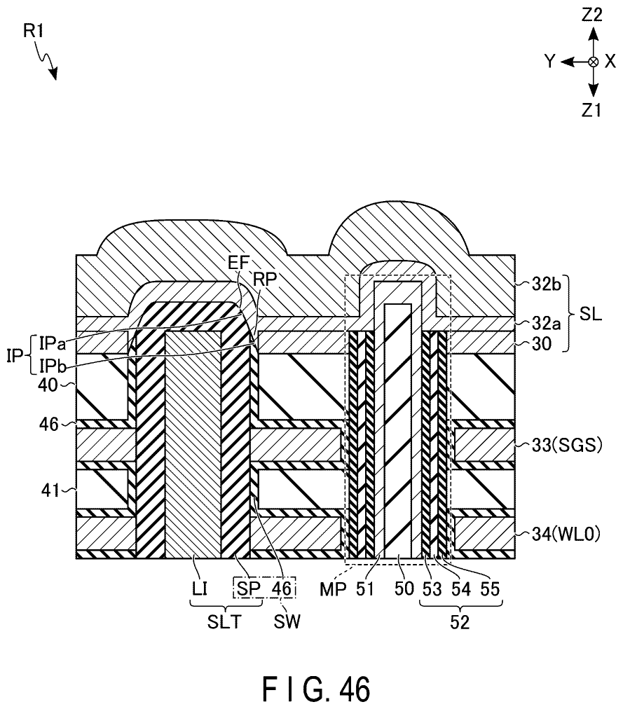

Next, details of cross-sectional structures of the layer stack SB and a vicinity of the layer stack SB will be described. FIG. 46 is an enlarged cross-sectional view of a partial region (region R1) including the layer stack SB of FIG. 45.

As illustrated in FIG. 46, the cross-sectional structure of each of the layer stack SB and the insulator SW is similar to that in FIG. 32 described in the fourth embodiment except that the end surface of the conductor LI in the Z2 direction is covered with the spacer SP. That is, the cross-sectional structure of each of the conductive layer 32a, the conductive layer 32b, and the insulator 46 is similar to that in FIG. 32 described in the fourth embodiment.

### 8.2 Method of Manufacturing Semiconductor Memory Device

A method of manufacturing the semiconductor memory device 3G will be described.

First, in a similar manner to the fifth embodiment, the member SLT is formed and processes up to a process of removing the natural oxide film on the second surface of the conductive layer 30 after removal of the stacked film 52 are performed. As a result, the structure illustrated in FIG. 36 is formed, similarly to the fifth embodiment.

Thereafter, similarly to the fourth embodiment, processes of removing the natural oxide film on the second surface of the conductive layer 30, forming the conductive layer 32a, and forming the conductive layer 32b are performed. As a result, the structure illustrated in FIG. 46 is formed.

### 8.3 Effects According to Present Embodiment

According to the present embodiment, effects similar to those of the fourth embodiment are obtained.

### 9. Modification and the Like

As described above, a semiconductor memory device (3) according to an embodiment includes: a substrate (71); a layer stack (SB) disposed above the substrate in a first direction (Z2); a first conductive layer (33/34/35) disposed between the substrate and the layer stack; a memory pillar (MP) including a semiconductor film (51), extending in the first direction, and penetrating the first conductive layer; and a first member (SLT) disposed apart from the memory pillar in a second direction (Y) intersecting the first direction, extending in the first direction, and penetrating the first conductive layer. The layer stack (SB) has a structure in which a first semiconductor layer (31a), a second semiconductor layer (31b), a second conductive layer (32a), and a third conductive layer (32b) are stacked in order from a side of the substrate (71). The first semiconductor layer (31a) covers an end portion of the semiconductor film (51) in the first direction (Z2) and an end portion of the first member (SLT) in the first direction.

Note that the embodiments are not limited to the above-described embodiments, and various modifications can be made.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate;
a layer stack disposed above the substrate in a first direction;
a first conductive layer disposed between the substrate and the layer stack;
a memory pillar that includes a semiconductor film, extends in the first direction, and penetrates the first conductive layer; and
a first member that is disposed apart from the memory pillar in a second direction intersecting the first direction, extends in the first direction, and penetrates the first conductive layer,
wherein the layer stack has a structure in which a first semiconductor layer, a second semiconductor layer, a second conductive layer, and a third conductive layer are stacked in order from a side of the substrate, and
the first semiconductor layer covers an end portion of the semiconductor film in the first direction and an end portion of the first member in the first direction.

2. The device according to claim 1, wherein a grain boundary of the first semiconductor layer and a grain boundary of the second semiconductor layer are discontinuous.

3. The device according to claim 2, wherein a grain diameter of the first semiconductor layer is different from a grain diameter of the second semiconductor layer.

4. The device according to claim 3, wherein the grain diameter of the first semiconductor layer is smaller than the grain diameter of the second semiconductor layer.

5. The device according to claim 2, wherein the layer stack has a structure in which an insulating layer is further provided between the first semiconductor layer and the second semiconductor layer.

6. The device according to claim 5, wherein the insulating layer is an oxide film or a nitride film.

7. The device according to claim 1, further comprising:
a fourth conductive layer that is disposed between the first conductive layer and the layer stack, is spaced apart from the first conductive layer in the first direction, and is in contact with the first semiconductor layer,
wherein the first member includes a conductor, and a first insulator that covers a side surface of the conductor in the second direction and an end surface of the conductor in the first direction,
an end surface of the first insulator in the first direction has an inclined portion on a side not in contact with the conductor, and
the inclined portion is in contact with the first semiconductor layer, and is in contact with the fourth conductive layer at a position below an upper surface of the fourth conductive layer in the first direction.

8. The device according to claim 7, wherein the first insulator includes a second insulator that covers the side surface of the conductor in the second direction and the end surface of the conductor in the first direction, and a third insulator that covers a side surface of the second insulator in the second direction.

9. The device according to claim 1, wherein the first semiconductor layer and the second semiconductor layer include polysilicon.

10. The device according to claim 1, further comprising:
a first chip including the substrate; and
a second chip including the layer stack, the first conductive layer, the memory pillar, and the first member,
wherein the second chip is bonded to the first chip.

11. The device according to claim 1, wherein the semiconductor memory device is a NAND flash memory.

12. A semiconductor memory device comprising:
a substrate;
a layer stack disposed above the substrate in a first direction;
a first conductive layer disposed between the substrate and the layer stack;
a memory pillar that includes a semiconductor film, extends in the first direction, and penetrates the first conductive layer; and
a first member that is disposed apart from the memory pillar in a second direction intersecting the first direction, extends in the first direction, and penetrates the first conductive layer,
wherein the layer stack has a structure in which a first semiconductor layer, a second conductive layer, and a third conductive layer are stacked in order from a side of the substrate,
the first member includes a conductor and a first insulator that covers a side surface of the conductor in the second direction, and
the first semiconductor layer covers an end portion of the semiconductor film in the first direction and an end portion of the conductor in the first direction.

13. The device according to claim 12, further comprising:
a fourth conductive layer that is disposed between the first conductive layer and the layer stack, is spaced apart from the first conductive layer in the first direction, and is in contact with the first semiconductor layer,
wherein an end surface of the first insulator in the first direction is located below an upper surface of the conductor in the first direction and an upper surface of the fourth conductive layer in the first direction, and
a side surface of the end portion of the conductor in the first direction and the end surface of the first insulator in the first direction are in contact with the first semiconductor layer.

14. The device according to claim 13, wherein the layer stack has a structure in which a second semiconductor layer is further provided between the first semiconductor layer and the second conductive layer.

15. The device according to claim 14, wherein the layer stack has a structure in which an insulating layer is further provided between the first semiconductor layer and the second semiconductor layer.

16. The device according to claim 12, wherein the first semiconductor layer includes polysilicon.

17. A semiconductor memory device comprising:
a substrate;
a layer stack disposed above the substrate in a first direction;
a first conductive layer disposed between the substrate and the layer stack;
a memory pillar that includes a semiconductor film, extends in the first direction, and penetrates the first conductive layer; and
a first member that is disposed apart from the memory pillar in a second direction intersecting the first direction, extends in the first direction, and penetrates the first conductive layer,
wherein the layer stack has a structure in which a second conductive layer and a third conductive layer are stacked in order from a side of the substrate, and
the second conductive layer covers an end portion of the semiconductor film in the first direction and an end portion of the first member in the first direction.

18. The device according to claim 17, further comprising:
a fourth conductive layer that is disposed between the first conductive layer and the layer stack, is spaced apart from the first conductive layer in the first direction, and is in contact with the second conductive layer;
wherein the first member includes a conductor, and a first insulator that covers a side surface of the conductor in the second direction and an end surface of the conductor in the first direction,
an end surface of the first insulator in the first direction has an inclined portion on a side not in contact with the conductor, and
the inclined portion is in contact with the second conductive layer, and is in contact with the fourth conductive layer at a position below an upper surface of the fourth conductive layer in the first direction.

19. The device according to claim 18, wherein the first insulator includes a second insulator that covers the side surface of the conductor in the second direction and the end surface of the conductor in the first direction, and a third insulator that covers a side surface of the second insulator in the second direction.

20. The device according to claim 17, wherein the second conductive layer includes titanium or titanium nitride, and
the third conductive layer includes tungsten.
